(19) United States
(12) Patent Application Publication
(10) Pub. No.: US 2025/0272890 A1
(43) Pub. Date: Aug. 28, 2025

(54) MAGNETIC RESONANCE IMAGING SYSTEMS AND METHODS

(71) Applicant: SHANGHAI UNITED IMAGING HEALTHCARE CO., LTD., Shanghai (CN)

(72) Inventor: Lingzhi HU, Houston, TX (US)

(73) Assignee: SHANGHAI UNITED IMAGING HEALTHCARE CO., LTD., Shanghai (CN)

(21) Appl. No.: 19/066,134

(22) Filed: Feb. 27, 2025

(30) Foreign Application Priority Data
Feb. 28, 2024 (CN) 202410224045.0

(51) Int. Cl. G06T 11/00; G06T 7/00

(52) U.S. Cl. CPC G06T 11/006; G06T 7/00; G06T 2207/10088

(57) ABSTRACT

Embodiments of the present disclosure provide a magnetic resonance imaging (MRI) system and method. The MRI system includes a signal receiving assembly and a data processor. The signal receiving assembly is configured to acquire a nuclear spin magnetic field signal of an object. The data processor is configured to generate a magnetic resonance image of the object based on the nuclear spin magnetic field signal. The signal receiving assembly includes a magnetic sensor array.

### CROSS-REFERENCE TO RELATED APPLICATIONS

This application claims priority to Chinese Application No. 202410224045.0 filed on Feb. 28, 2024, the entire contents of which are hereby incorporated by reference.

### TECHNICAL FIELD

The present disclosure relates to the technical field of medical devices, and in particular, to magnetic resonance imaging systems and methods.

### BACKGROUND

In magnetic resonance imaging (MRI), the magnetic fields mainly include a static magnetic field, a gradient magnetic field, and a radiofrequency emission field. Currently, the monitoring of the magnetic fields such as the static magnetic field, the gradient magnetic field, and the radiofrequency emission field in MRI is based on the spin magnetic resonance (NMR) effect. However, magnetic field measurement and monitoring based on the NMR effect relies on a complex transmitter and receiver links which are electronically and logically complex with a higher cost costly, and poor universality. Thus, the magnetic field measurement and monitoring based on the NMR effect is usually only applicable to the manufacturers of MRI devices and not available for daily clinical use in the actual application sites (e.g., hospitals) of MRI devices.

Based on this, it is desirable to provide a magnetic resonance imaging (MRI) system to enhance the efficacy and quality of MRI.

### SUMMARY

One or more embodiments of the present disclosure provide a magnetic resonance imaging (MRI) system. The MRI system may include a signal receiving assembly configured to acquire a magnetic resonance signal of an object and a data processor configured to generate a magnetic resonance image of the object based on the magnetic resonance signal. The signal receiving assembly may include one or more magnetic sensors.

In some embodiments, the one or more magnetic sensors may include a plurality of first magnetic sensors arranged non-uniformly.

In some embodiments, a count and/or layout of the one or more magnetic sensors may be determined based on a region of interest of the object.

In some embodiments, the one or more magnetic sensors may be arranged to form a planar structure or a three-dimensional (3D) structure.

In some embodiments, the one or more magnetic sensors may be configured to monitor physiological information of the object.

In some embodiments, the MRI system may further include a first monitoring assembly. The first monitoring assembly may include at least one second magnetic sensor configured to monitor magnetic field distribution information of a static magnetic field and/or a gradient field of the MRI system.

In some embodiments, a detection region of the at least one second magnetic sensor may be configured to cover an examination region of the MRI system, and the magnetic field distribution information may include at least one of a temporal distribution or a spatial distribution of the static magnetic field and/or the gradient field of the MRI system.

In some embodiments, one of the at least one second magnetic sensor may be configured to move in the static magnetic field and/or the gradient field of the MRI system.

In some embodiments, a count of second magnetic sensors that are configured to move in the static magnetic field and/or the gradient field of the MRI system may be less than a preset threshold.

In some embodiments, the one of the at least one second magnetic sensor may be configured to move in an axial direction or a circumferential direction along an aperture of the MRI system.

In some embodiments, a second magnetic sensor configured to monitor the static magnetic field may have a different measurement accuracy and/or a different sampling rate than a second magnetic sensor configured to monitor the gradient field.

In some embodiments, the MRI system may further include a second monitoring assembly. The second monitoring assembly may include one or more third magnetic sensors, and the second monitoring assembly may be configured to monitor operation information of the MRI system.

In some embodiments, the second monitoring assembly may be provided at an edge of a scanning bed or an edge of an aperture of the MRI system.

In some embodiments, the one or more third magnetic sensors may be different from the one or more magnetic sensors of the signal receiving assembly.

In some embodiments, the MRI system may further include a third monitoring assembly. The third monitoring assembly may include one or more fourth magnetic sensors, and the third monitoring assembly may be configured to perform metal detection

In some embodiments, the third monitoring assembly may be provided within a scanning chamber, at the edge of the scanning bed, or on a frame of the MRI system.

One or more embodiments of the present disclosure provide a magnetic resonance imaging (MRI) method. The (MRI) method may include acquiring a magnetic resonance signal of an object collected by one or more magnetic sensors in an MRI device; determining K-space data based on the magnetic resonance signal; and obtaining a magnetic resonance image of the object by image reconstruction based on the K-space data.

In some embodiments, the acquiring a magnetic resonance signal of an object collected by one or more magnetic sensors in an MRI device may include turning off at least one of a static magnetic field or a gradient field of the MRI device during a process of acquiring the magnetic resonance signal of the object.

In some embodiments, the MRI method may further include monitoring magnetic field distribution information of a static magnetic field and/or a gradient field using a first monitoring assembly of the MRI device, the first monitoring assembly including at least one second magnetic sensor.

In some embodiments, the MRI method may further include monitoring device operation information using a second monitoring assembly of the MRI device, the second monitoring assembly including one or more third magnetic sensors and/or performing metal detection using a third monitoring assembly of the MRI device, the third monitoring assembly including one or more fourth magnetic sensors, the metal detection including monitoring whether a redundant metal presents in a monitoring region, the monitoring region at least including a scanning bed.

### BRIEF DESCRIPTION OF THE DRAWINGS

The present disclosure is further illustrated in terms of exemplary embodiments. These exemplary embodiments are described in detail with reference to the drawings. These embodiments are non-limiting exemplary embodiments, in which like reference numerals represent similar structures, and wherein:

FIG. 1 is a schematic diagram illustrating an exemplary magnetic resonance imaging system according to some embodiments of the present disclosure;

FIG. 2 is a schematic diagram illustrating an exemplary magnetic resonance imaging system according to some embodiments of the present disclosure;

FIG. 3 is a schematic diagram illustrating an exemplary magnetic sensor according to some embodiments of the present disclosure;

FIG. 4 is a schematic diagram illustrating a bridge circuit according to some embodiments of the present disclosure;

FIG. 5A is a schematic diagram illustrating a magnetic sensor array according to some embodiments of the present disclosure;

FIG. 5B is a schematic diagram illustrating a magnetic sensor array according to some other embodiments of the present disclosure;

FIG. 5C is a schematic diagram illustrating a magnetic sensor array according to some other embodiments of the present disclosure;

FIG. 6 is a schematic diagram illustrating a magnetic resonance imaging system according to other embodiments of the present disclosure;

FIG. 7 is a schematic diagram illustrating a magnetic resonance imaging system according to some other embodiments of the present disclosure;

FIG. 8 is a schematic diagram illustrating modules of a magnetic resonance imaging system according to some embodiments of the present disclosure; and

FIG. 9 is a flowchart illustrating an exemplary magnetic resonance imaging method according to some embodiments of the present disclosure.

### DETAILED DESCRIPTION

To more clearly illustrate the technical solutions related to the embodiments of the present disclosure, a brief introduction of the drawings referred to the description of the embodiments is provided below. Obviously, the drawings described below are only some examples or embodiments of the present disclosure. Those having ordinary skills in the art, without further creative efforts, may apply the present disclosure to other similar scenarios according to these drawings. Unless obviously obtained from the context or the context illustrates otherwise, the same numeral in the drawings refers to the same structure or operation.

It should be understood that “system”, “device”, “unit” and/or “module” as used herein is a manner used to distinguish different components, elements, parts, sections, or assemblies at different levels. However, if other words serve the same purpose, the words may be replaced by other expressions.

As shown in the present disclosure and claims, the words “one”, “a”, “a kind” and/or “the” are not especially singular but may include the plural unless the context expressly suggests otherwise. In general, the terms “comprise”, “comprises”, “comprising”, “include”, “includes”, and/or “including”, merely prompt to include operations and elements that have been clearly identified, and these operations and elements do not constitute an exclusive listing. The methods or devices may also include other operations or elements.

The flowcharts used in the present disclosure illustrate operations that systems implement according to some embodiments of the present disclosure. It should be understood that the previous or subsequent operations may not be accurately implemented in order. Instead, each step may be processed in reverse order or simultaneously. Meanwhile, other operations may also be added to these processes, or a certain step or several steps may be removed from these processes.

As mentioned above, magnetic field measurements in magnetic resonance imaging (MRI) are currently based on the nuclear magnetic resonance (NMR) effect. In other words, the static magnetic field, the gradient magnetic field, and the radiofrequency (RF) emission field are monitored based on the NMR effect. However, the magnetic field measurements in magnetic resonance imaging (MRI) based on the nuclear magnetic resonance (NMR) effect relies on complex transmitter and receiver links and is electronically and logically complex, costly, and less generalizable, which is typically used only by the manufacturers of the devices and not available for daily clinical use in the actual application sites (e.g., hospitals) of the devices.

The principle of MRI is primarily based on a strong magnetic field that produces a nuclear spin magnetic field, a gradient magnetic field that produces spatial coding, and an RF coil that produces resonance excitation and receives signals. However, existing magnetic resonance imaging devices have the following three problems. First, generating the nuclear spin magnetic field by a strong magnetic field provided by an MRI device not only results in a large size of the MRI device, but also requires liquid helium to cool the MRI device. Second, the gradient magnetic field provided by the MRI device may generate a huge noise when subjected to the strong magnetic field. Third, the resonance excitation and receiving signals are generated by the RF coil of the MRI device, which needs to be wrapped around the object. The limited number of channels in the RF coil results in high imaging limitations, in addition to the low signal-to-noise ratio of the signals received by the RF coil.

Currently, in order to solve the above three problems of the MRI devices and other technical problems that constrain the cost and wide application of the MRI devices, a variety of MRI devices with ultra-low magnetic fields (e.g., 0.55 T, 0.3 T, 0.065 T, etc.) have been generated. With the weakening of the magnetic field, the first problem and second problem are better solved, but the quality of the MRI deteriorates. At the same time, since such ultra-low-field MRI devices inherently do not change the acquisition of magnetic resonance signals, RF receiving coils are still used for the reception or acquisition of the magnetic resonance signals.

In some embodiments, various types of magnetic sensors (e.g., a tunnel magneto resistance (TMR) sensor) have a measurement accuracy ranging from the microtesla (μT) range to the picotesla (pT) or even femtotesla (fT) range, and the manufacturing cost is reduced significantly, which undoubtedly provides a better opportunity for its widespread application in the medical field. Based on this, magnetic sensors may be introduced in the MRI devices in order to solve all or part of the above-mentioned 3 problems in the MRI device.

An MRI system provided in embodiments of the present disclosure uses magnetic sensors to monitor a temporal distribution and/or a spatial distribution of a static magnetic field and/or a gradient magnetic field in real time. In addition, the MRI system replaces the original RF receiving coils in the MRI devices with a signal receiving assembly including a magnetic sensor array (e.g., a tunneling magneto-resistive effect sensor array) to receive nuclear spin magnetic field signals from the human body. Thus, the efficiency and quality of MRI may be improved.

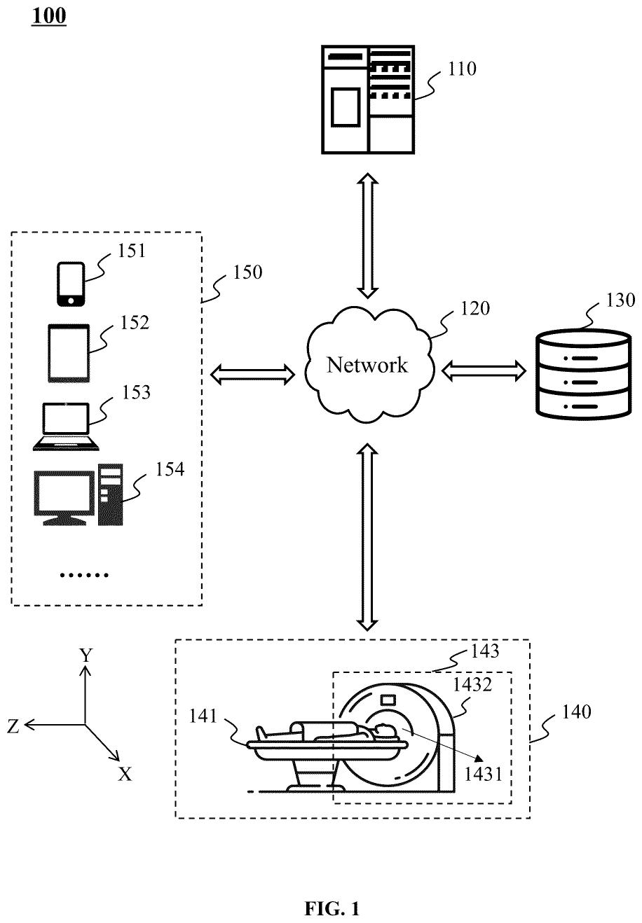

FIG. 1 is a schematic diagram illustrating an exemplary magnetic resonance imaging system according to some embodiments of the present disclosure. In some embodiments, as shown in FIG. 1, an application scenario 100 of a magnetic resonance imaging (MRI) system (hereinafter referred to as the application scenario 100) includes a processing device 110, a network 120, a storage device 130, an MRI device 140, and a terminal device 150.

The processing device 110 refers to a device for processing data and/or information from at least one component of the application scenario 100 or an external data source (e.g., a cloud data center). The processing device 110 may access data or information from the storage device 130, the MRI device 140, and/or the terminal device 150 via the network 120. The processing device 110 may also be directly connected to storage device 130, the MRI device 140, and/or the terminal device 150 to access information and/or data. For example, the processing device 110 may obtain, from the MRI device 140, a nuclear spin magnetic field signal of an object acquired by the MRI device 140 (e.g., the nuclear spin magnetic field signal of the object acquired by a signal receiving assembly). As another example, the processing device 110 may determine K-space data of the object based on the nuclear spin magnetic field signal and obtain a magnetic resonance image of the object by image reconstruction based on the K-space data. As yet another example, the processing device 110 may determine a temporal distribution and/or a spatial distribution of the static magnetic field and/or the gradient field of the MRI device 140 based on magnetic field monitoring data of the MRI device 140 (e.g., monitoring data acquired by a first monitoring assembly).

The network 120 may connect various components of the application scenario 100 and/or connect the application scenario 100 to an external resource portion. In some embodiments, information and/or data may be exchanged between one or more components of the application scenario 100 (e.g., the processing device 110, the storage device 130, the MRI device 140, and/or the terminal device 150) via the network 120.

In some embodiments, the network 120 is any one or more of a wired network or a wireless network. In some embodiments, the network 120 includes one or more network access points. For example, the network 120 includes wired or wireless network access points (e.g., base stations and/or network switching points) through which one or more components of the application scenario 100 may be connected to the network 120 to exchange data and/or information.

The storage device 130 refers to a device for storing data, instructions, and/or any other information. In some embodiments, the storage device 130 stores data and/or information obtained from, for example, the processing device 110, the MRI device 140, and/or the terminal device 150. For example, the storage device 130 may store the nuclear spin magnetic field signal of the object acquired by the MRI device 140. As another example, the storage device 130 may store the magnetic resonance image of the object, the temporal distribution and/or the spatial distribution of the static magnetic field of the MRI device 140, the temporal distribution and/or the spatial distribution of the gradient magnetic field, or the like. In some embodiments, the storage device 130 may include one of mass storage, removable memory, or the like, or any combination thereof.

The MRI device 140 is configured to image a region of interest of the object based on the principle of magnetic resonance to obtain the magnetic resonance image of the object. The MRI device 140 uses a strong magnetic field, a gradient magnetic field, and radio waves to generate the magnetic resonance signal of an object to be scanned. In some embodiments, the MRI device 140 includes a magnet assembly and a gradient coil assembly. The magnet assembly may generate a first magnetic field (also known as a static or primary static magnetic field) used to polarize the object. The gradient coil assembly may be used to generate a second magnetic field (also known as a gradient field or gradient magnetic field).

In some embodiments, the MRI device 140 further includes one or more radiofrequency (RF) transmitting coils, a signal receiving assembly, and a data processor. The RF transmitting coil may transmit RF signals (e.g., RF pulses) to the object. In concert with the static or gradient magnetic field and the RF pulses, a magnetic resonance signal in relation to the object may be generated based on a pulse sequence. The magnetic resonance signal may also be referred to as an echo signal. The signal receiving assembly may obtain the magnetic resonance signal (e.g., the nuclear spin magnetic field signal of the object) based on the pulse sequence. The signal receiving assembly may include a magnetic sensor array configured to acquire the nuclear spin magnetic field signal of the object. The data processor is configured to generate the magnetic resonance image of the object based on the nuclear spin magnetic field signal. For example, the data processor may perform a transform operation (e.g., a Fourier transform) to process the nuclear spin magnetic field signal of the object to fill the K-space to obtain K-space data, which in turn generates the magnetic resonance image of the object. The K-space may be a two-dimensional K-space or a three-dimensional K-space. In some embodiments, the data processor may be integrated into the processing device 110.

In some embodiments, as shown in FIG. 1, the MRI device 140 includes a frame 1432 and a scanning aperture 1431. Components such as a magnet assembly, a gradient coil assembly, and an RF transmitting coil may be mounted on the frame 1432. The scanning aperture 1431 is also known as the examination region of the MRI device 143.

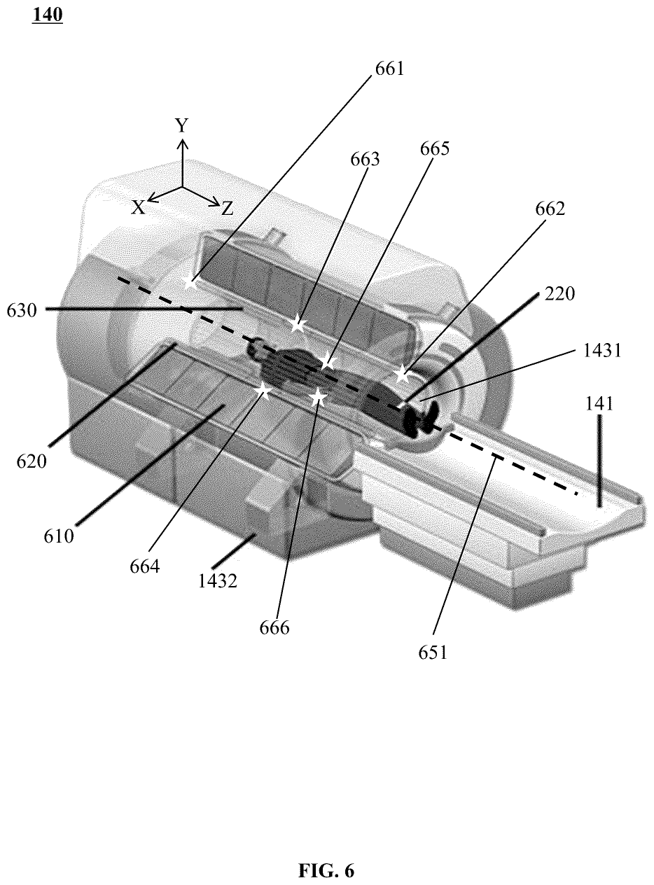

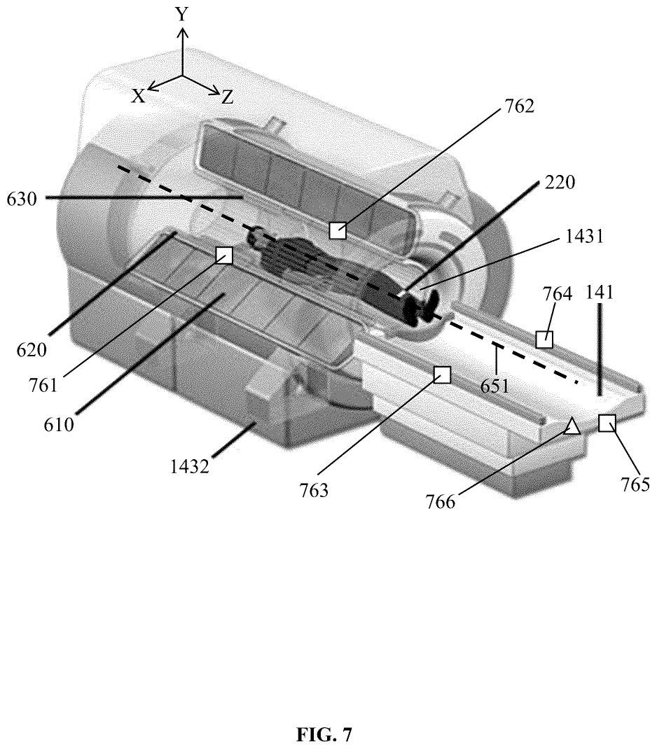

In some embodiments, as shown in FIG. 1, the MRI device 140 may include a scanning bed 141 for carrying an object. In some embodiments, the scanning bed 141 is moved relative to other portions of the MRI device 140 (e.g., the frame 1432 of the MRI device 140). For example, the scanning bed 141 may be moved back and forth along a Z-axis direction shown in FIG. 1, with the Z-axis direction being a direction parallel to a center axis of the scanning aperture 1431 of the MRI device 140 (e.g., the center axis 651 shown in FIG. 6 or FIG. 7). In some embodiments, the scanning bed 141 is independent of the MRI device 140. For example, the MRI device 140 and the scanning bed 141 are two mutually independent devices. In some embodiments, the scanning bed 141 is a part of the MRI device 140.

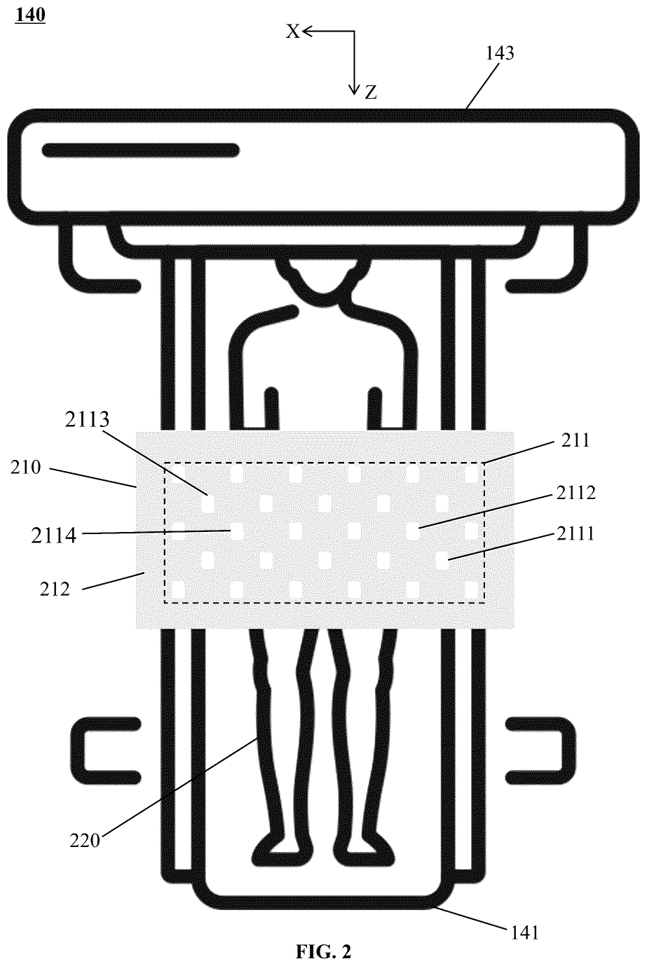

In some embodiments, the MRI device 140 further includes a first monitoring assembly, a second monitoring assembly, and a third monitoring assembly. More details may be found in the descriptions in FIG. 2, FIG. 6, and FIG. 7.

The terminal device 150 refers to one or more terminals or software used by a user (e.g., a physician, researcher, etc., using the MRI device 140) or the object of the MRI device 140. In some embodiments, as shown in FIG. 1, the terminal device 150 may include, but is not limited to, a smartphone 151, a tablet 152, a laptop 153, a desktop computer 154, or the like. In some embodiments, the terminal device 150 may interact with other components in the application scenario 100 via the network 120. For example, the end device 150 may acquire the magnetic resonance image determined by the processing device 110 over the network 120 and output it to the user. As another example, the end device 150 may control the imaging process of the MRI device 140 (e.g., turn off the static magnetic field and/or gradient magnetic field of the MRI device 140) via the network 120.

In some embodiments, the processing device 110 may be a part of the MRI device 140. For example, the processing device 110 may be configured within or outside of the MRI device 140 for performing functions performed by the data processor and/or determining distribution information of the static magnetic field and/or gradient magnetic field. As another example, the processing device 110 is a remote processor of the MRI device 140, which may be in a different physical space than the MRI device 140 (e.g., the processing device 110 is located in the operator's room and the MRI device 140 is located in the scanning room).

FIG. 2 is a schematic diagram illustrating an exemplary magnetic resonance imaging system according to some embodiments of the present disclosure. As shown in FIG. 2, the MRI device 140 includes a signal receiving assembly 210.

The signal receiving assembly 210 is configured to acquire a nuclear spin magnetic field signal from an object (e.g., object 220).

In some embodiments, the object includes a body, a substance, etc., or any combination thereof. In some embodiments, the object includes a particular portion of the body, e.g., the head, the chest, the abdomen, etc., or any combination thereof. In some embodiments, the object includes a particular organ, for example, the heart, the esophagus, the trachea, the bronchus, the stomach, the gallbladder, the small intestine, the colon, the bladder, the ureter, the uterus, the fallopian tube, or the like. In some embodiments, the object includes a patient or other medical experimental object (e.g., an animal such as a test mouse or a phantom), or the like.

Some nuclei (e.g., hydrogen nuclei) have spin properties, and such nuclei produce electromagnetic wave at specific resonance frequencies in an external magnetic field. For example, during MRI of the object, the object is placed in an examination region of the MRI device (e.g., in the scanning aperture 1431), a magnet assembly of the MRI device generates a static magnetic field (e.g., a static magnetic field generated using a superconducting magnet) in the examination region, and the static magnetic field results in the spin of a hydrogen nucleus in the body of the object to be aligned in the direction of the static magnetic field. The spined hydrogen nucleus may be partly in the direction of the static magnetic field and partly in the opposite direction of the static magnetic field, forming a tiny magnetization vector. When an RF pulse that matches the Larmor frequency (which is related to the strength of the static magnetic field) of the hydrogen nucleus is applied, the hydrogen nucleus may absorb energy and deviate from its initial direction. The RF pulse serves to flip the magnetization vector into a direction at the right angle to the direction of the static magnetic field, and when the emission of the RF pulse is ceased, the hydrogen nucleus releases energy and returns to a state where its direction is aligned with the direction of the static magnetic field.

When hydrogen nucleus releases energy, changes of a near-magnetization vector of the hydrogen nucleus (near-magnetization vector includes a near-magnetization vector size and a near-magnetization vector direction) may be received by the signal receiving assembly, and a sum of the change amount of the near-magnetization vectors of all hydrogen nuclei of the object is the nuclear spin magnetic field signal. The nuclear spin magnetic field signal may be characterized based on the relationship curve between an electrical signal output by a bridge circuit in the magnetic sensor array and time. More descriptions regarding the magnetic sensor array, the first magnetic sensor, and the bridge circuit may be found later.

In some embodiments, as shown in FIG. 2, the signal receiving assembly 210 includes a magnetic sensor array 211. The signal receiving assembly 210 may be configured to acquire a nuclear spin magnetic field signal of an object via the magnetic sensor array 211.

The magnetic sensor array 211 refers to an array including one or more first magnetic sensors (e.g., a first magnetic sensor 2111, a first magnetic sensor 2112, etc.). The signal receiving assembly 210 may include a carrier 212. The one or more first magnetic sensors forming the magnetic sensor array 211 may be connected (e.g., sewn or affixed) to the carrier 212 to form the signal receiving assembly 210.

The magnetic sensor array 211 may be disposed within or on the surface of the carrier 212. For example, the first magnetic sensors may be sewn or affixed to the surface of the carrier uniformly or non-uniformly. In some embodiments, the carrier 212 may include an intermediate layer and a wrapper layer (not shown in the figures). The first magnetic sensors may be sewn or affixed to the intermediate layer, and the wrapper layer may overlay outside the intermediate layer, wrapping the intermediate layer and the first magnetic sensors.

The carrier 212 may be overlaid on a region of interest of the object during imaging. For example, as shown in FIG. 2, with the region of interest being the abdomen of the object 220, when the object 220 is lying flat on the scanning bed 141, the carrier 212 may be covered on the abdomen of the object 220 so that the magnetic sensor array 211 may acquire a nuclear spin magnetic field signal from the abdomen of the object 220.

The material of the carrier 212 may be rigid (e.g., the same material as a housing of the MRI device) or soft (e.g., a soft plastic, textile, etc.). In some embodiments, the magnetic sensor array 211 may be in contact with the region of interest of the object. For example, when the carrier 212 is a soft material, the carrier 212 may wrap around the surface of the region of interest of the object by deforming. In some embodiments, the magnetic sensor array 211 may not be in contact with the region of interest of the object. For example, the carrier 212 may be a rigid material, and the carrier 212 may support the magnetic sensor array 211 so that the magnetic sensor array 211 is positioned at a certain height above the region of interest of the object.

A first magnetic sensor (e.g., the first magnetic sensor 2111 and the first magnetic sensor 2112) refers to a sensing device capable of sensing information about a magnetic field (e.g., the magnetic induction strength of the magnetic field) and changing the resistance value thereof based on changes in the magnetic field. For example, the magnetic sensor array 211 may include a tunnel magneto resistance (TMR) sensor, a graphene sensor, a Hall sensor, etc., or a combination thereof. For example, the magnetic sensor array 211 may include a plurality of TMR sensors. As another example, the magnetic sensor array 211 may include a plurality of graphene sensors. As yet another example, the magnetic sensor array 211 may include a plurality of TMR sensors and a plurality of graphene sensors.

In some embodiments, the first magnetic sensor (e.g., the first magnetic sensor 2111, the first magnetic sensor 2112, etc.) is a TMR sensor, i.e., the magnetic sensor array 211 refers to an array consisting of a plurality of TMR sensors. In some embodiments, when the nuclear spin magnetic field signal of the object is collected using a TMR array, the magnet assembly in the magnetic resonance imaging device is preferably an ultra-low field magnet (e.g., a magnet below 0.6 T) assembly or a variable magnet assembly (e.g., the magnetic induction intensity of the device can be switched between multiple intensity values or a preset interval).

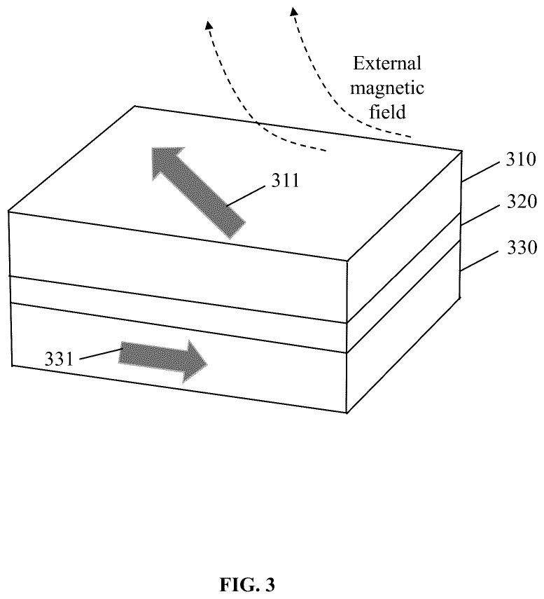

FIG. 3 is a schematic diagram illustrating an exemplary magnetic sensor according to some embodiments of the present disclosure. The magnetic sensor as shown in FIG. 3 may be a magnetic multilayer structure including a free layer 310, a non-magnetic layer 320, and a pinning layer 330.

The free layer 310 refers to a layer that is free to change a magnetization direction. A magnetization direction 311 of the free layer 310 may change with the external magnetic field (e.g., the static magnetic field, the gradient magnetic field, etc.), and the change of the magnetization direction 311 may affect the resistance characteristics of the entire magnetic multilayer structure (i.e., the magnetic sensor). The free layer 310 may include a magnetic material. For example, the free layer 310 may include a nickel-iron alloy or a cobalt-iron alloy.

The non-magnetic layer 320 cannot be magnetized. The non-magnetic layer 320 includes an insulating material, e.g., the non-magnetic layer 320 may include, for example, alumina or silicon nitride, etc.

The pinning layer 330 refers to a layer of the magnetic multilayer structure having a fixed magnetization direction. That is, a magnetization direction 331 of the pinning layer 330 remains constant during an MRI process and is therefore also referred to as a fixed layer. The pinning layer 330 may be kept in a fixed magnetization state by coupling with the non-magnetic layer 320. The pinning layer 330 may include a conductor material, for example, the pinning layer 330 may include copper or aluminum, etc.

The equivalent resistance of the magnetic sensor depends on the relative angle between the magnetization direction 331 of the pinning layer 330 and the magnetization direction 311 of the free layer 310. For the giant magnetoresistance (GMR) effect, the change in the resistance of the magnetic sensor is due to spin-dependent scattering. For the TMR effect, the change in the resistance of the magnetic sensor is due to the spin-dependent tunneling effect of the electrons as the electrons pass through the tunneling barrier (usually an oxide layer).

Specifically, when the magnetization direction 311 of the free layer 310 and the magnetization direction 331 of the pinning layer 330 are the same (i.e., an angle between the magnetization direction 311 of the free layer 310 and the magnetization direction 331 of the pinning layer 330 is) 0°, the resistance of the magnetic sensor is relatively low. When the magnetization direction 311 of the free layer 310 and the magnetization direction 331 of the pinning layer 330 are inverse (i.e., the angle between the magnetization direction 311 of the free layer 310 and the magnetization direction 331 of the pinning layer 330 is 180°), the resistance of the magnetic sensor is relatively high. Understandably, the greater the angle between the magnetization direction 311 of the free layer 310 and the magnetization direction of the pinning layer 330, the greater the resistance of the magnetic sensor.

Based on the above principle of operation of the magnetic sensor, the change in the external magnetic field where the magnetic sensor is located may be determined by detecting the change in the resistance of the magnetic sensor. Specifically, the change in the external magnetic field may cause the change in the magnetization direction 311 of the free layer 310, whereas the magnetization direction 331 of the pinning layer 330 is constant. Thus, the above-described change in the external magnetic field may cause the change in the angle between the magnetization direction 311 of the free layer 310 and the magnetization direction 331 of the pinning layer 330, thereby causing the change in the resistance of the magnetic sensor.

In some embodiments, for example, after the magnetic sensor is connected to the bridge circuit, by obtaining electrical information (e.g., current information or voltage information, etc.) output from the bridge circuit, a resistance value of the magnetic sensor may be determined in combination with other conditions of the bridge circuit (e.g., a circuit structure, a value of Vcc), and the magnetic strength and the direction of the external magnetic field (e.g., the static magnetic field, the gradient magnetic field, etc.) where the magnetic sensor is located are deduced according to the resistance value of the magnetic sensor.

In some embodiments, further, the change in the resistance of the magnetic sensor results in the change in the overall resistance of the bridge circuit. When other conditions (e.g., the circuit structure, the value of Vcc) remain unchanged, the above change in the overall resistance of the bridge circuit may result in a change in the electrical information (e.g., current information or voltage information, etc.) output by the bridge circuit. On this basis, the change in the resistance of the magnetic sensor may be obtained based on the change in the electrical information of the bridge circuit, thereby obtaining the change (e.g., change in intensity, change in direction, etc.) in the external magnetic field (the static magnetic field, the gradient magnetic field, etc.) where the magnetic sensor is located.

Accordingly, with reference to the foregoing, by utilizing the magnetic sensor array consisting of a plurality of the first magnetic sensors as the signal receiving assembly, information on the change of the near-magnetization vector generated when energy is released from the hydrogen nucleus in the body of the object may be obtained to obtain the nuclear spin magnetic field signal of the object.

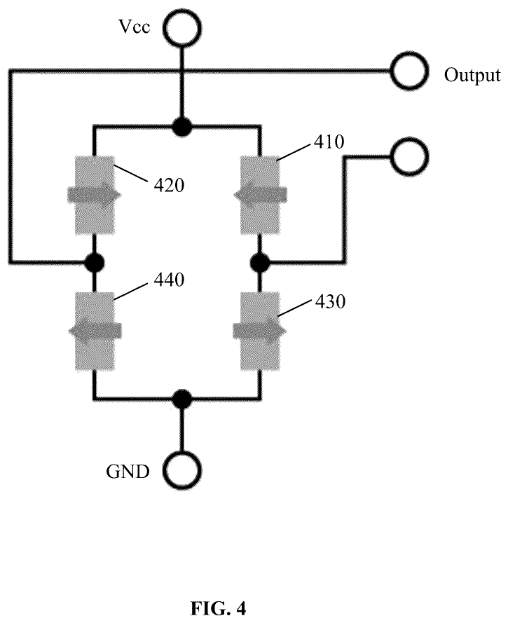

FIG. 4 is a schematic diagram illustrating a bridge circuit according to some embodiments of the present disclosure. The bridge circuit shown in FIG. 4 includes four magnetic sensors (i.e., a magnetic sensor 410, a magnetic sensor 420, a magnetic sensor 430, and a magnetic sensor 440). The direction of the arrow on a magnetic sensor represents the magnetization direction of the pinning layer of the magnetic sensor. When the resistance value of the magnetic sensor changes due to changes in the external magnetic field, the potential value of an output of the bridge circuit shown in FIG. 4 changes accordingly.

It should be noted that the bridge circuit shown in FIG. 4 is intended as an example only, and in some embodiments, the number of magnetic sensors accessed in the bridge circuit may be other values (e.g., 2, 6, etc.), and the magnetic sensors may be connected in other series or parallel connections, which are not limited by the present disclosure.

The plurality of first magnetic sensors in the magnetic sensor array may be connected to the same bridge circuit or may be separately connected to a plurality of bridge circuits having the same circuit structure. For example, there are 100 first magnetic sensors in the magnetic sensor array 211, and the 100 first magnetic sensors may be connected to 25 bridge circuits as shown in FIG. 4 in groups of 4.

In some embodiments, the magnetic sensor array includes a planar structure or a three-dimensional stereoscopic structure.

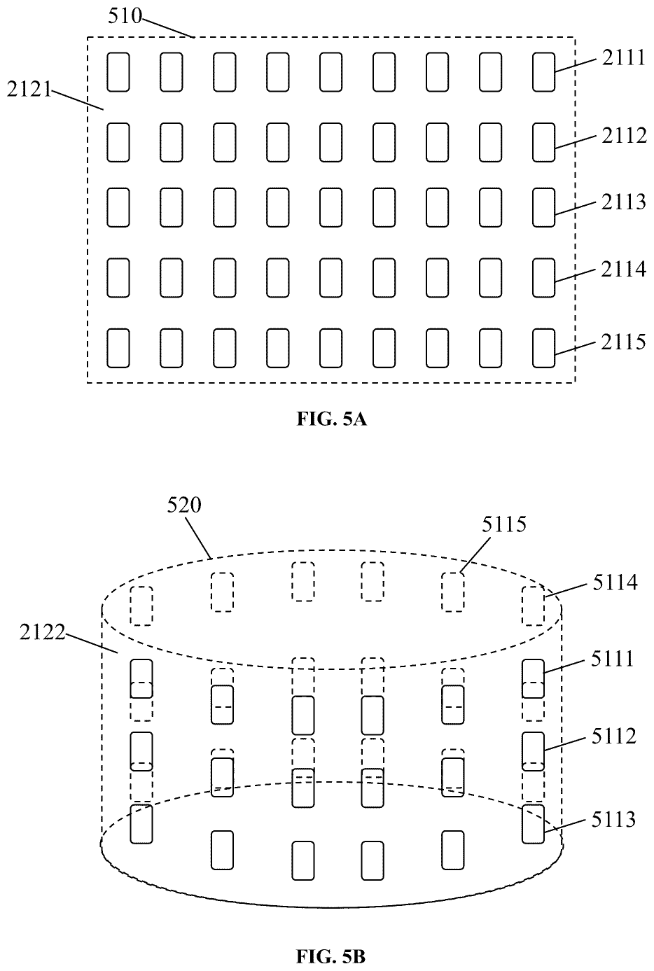

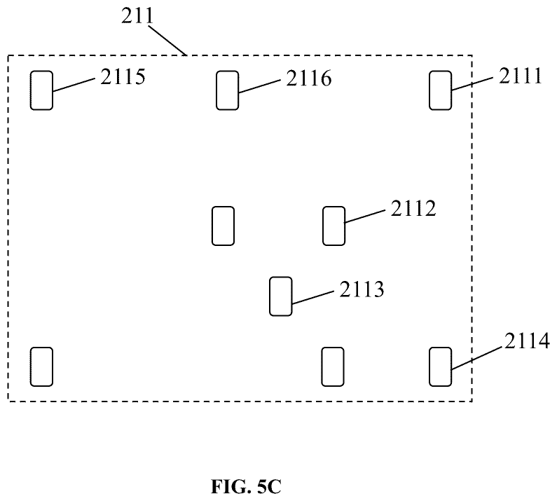

FIG. 5A is a schematic diagram illustrating an exemplary signal receiving assembly according to some embodiments of the present disclosure. FIG. 5B is a schematic diagram illustrating another exemplary signal receiving assembly according to some embodiments of the present disclosure. FIG. 5C is a schematic diagram illustrating another exemplary signal receiving assembly according to some embodiments of the present disclosure. The outermost dashed box in each of FIGS. 5A, 5B, and 5C represent a carrier of a signal receiving assembly, the small rectangular solid and dashed boxes within the outermost dashed box represent first magnetic sensors of the signal receiving assembly, the small rectangular solid box indicates that the current viewing angle shown is visible, and the small rectangular dashed box indicates that the current viewing angle shown is invisible.

Exemplarily, as shown in FIG. 5A, a plurality of first magnetic sensors 2111, 2112, 2113, 2114, 2115, etc., as indicated by the solid rectangular boxes, are sewed or affixed to the carrier 2121 indicated by the dashed rectangular box to form a planar-structured signal receiving assembly 510. In a natural state (when not being used), the plurality of first magnetic sensors 2111, 2112, 2113, 2114, 2115, etc., of the signal receiving assembly 510 are in the same plane, and the signal receiving assembly 510 is a planar structure similar to paper. Furthermore, when in use, a region of interest of the object may be covered or wrapped by the signal receiving assembly via flattening, folding, or bending the carrier 2121. For example, the first and last ends (left and right ends or top and bottom ends in FIG. 5A) of the carrier 2121 may be joined by a snap connection, a Velcro connection, or the like, such that the signal receiving assembly wraps around the object's legs, neck, arms, and other regions of interest. As another example, the signal receiving assembly 510 may be made to cover the region of interest such as the abdomen or chest of the object by the carrier 2121 by being placed flat on the abdomen, the chest, etc., of the object. The region of interest refers to a region of an object to be imaged, for example, the region of interest may be the abdomen, legs, chest, neck, or the like of the patient.

As yet another exemplary embodiment, as shown in FIG. 5B, a plurality of the first magnetic sensors 5111, 5112, 5113, 5114, 5115, or the like represented by the solid rectangular box and the dashed rectangular box are formed by sewing or affixing them on the carrier 2122 of the three-dimensional structure represented by the dashed columns to form a signal receiving assembly 520 of the three-dimensional structure. In FIG. 5B, the plurality of first magnetic sensors 5111, 5112, 5113, 5114, 5115, etc., are on a circumferential surface of a columnar three-dimensional structure. When in use, the signal receiving assembly 520 of the three-dimensional structure may be sheathed on the region of interest of the object (e.g., the leg, head, neck, etc. of the object), that is, the region of interest of the object is located within the cylindrical hollow space of the cylindrical three-dimensional structure, and the signal receiving assembly 520 wraps around the region of interest of the object.

It is understood that the shapes of the magnetic sensor arrays shown in FIG. 5A and FIG. 5B are only examples. In some embodiments, the shape of the magnetic sensor array or the shape of the carrier may be other planar shapes (e.g., circular, elliptical, polygonal, irregular), or other three-dimensional shapes (e.g., cubes, three-dimensional structures that fit different parts of the human body (e.g., the head, elbows, knees, neck, etc.), which are not limited in the present disclosure.

In some embodiments, the magnetic sensor array includes a plurality of first magnetic sensors arranged uniformly. The uniform arrangement means that a spacing between two adjacent first magnetic sensors in the plurality of first magnetic sensors are the same (e.g., as shown in FIG. 2, FIG. 5A, or FIG. 5B). Two adjacent first magnetic sensors means that no other first magnetic sensor exists between the two adjacent first magnetic sensors. A spacing of two adjacent first magnetic sensors may be preset manually. For example, the spacing of the two adjacent first magnetic sensors may be preset to 1 mm or 5 mm or 1 cm, etc. The spacing of the two adjacent first magnetic sensors may be determined based on the region of interest of the object. For example, for relatively irregularly shaped parts such as the head, joints, etc., the spacing of the two adjacent first magnetic sensors may be relatively small (e.g., 2.5 mm, 3 mm, 3.5 mm, 4 mm, 4.5 mm, 5 mm, 5.5 mm, etc.) to obtain more detailed and accurate information about the tissue structure. For relatively more regularly shaped parts such as the leg, the arm, and the chest cavity, the spacing between the two adjacent first magnetic sensors may be relatively large (e.g., for 1 cm, 3 cm, 5 cm, 7 cm, 9 cm, etc.).

In some embodiments, the magnetic sensor array 211 includes a plurality of first magnetic sensors non-uniformly arranged. The non-uniform arrangement means that a spacing between two adjacent first magnetic sensors among the plurality of first magnetic sensors included in the magnetic sensor array 211 is different from a spacing between another two adjacent first magnetic sensors. Specifically, there exists at least one set of two adjacent first magnetic sensors with a spacing that is different from the spacing of other sets of two adjacent first magnetic sensors. For example, as shown in FIG. 5C, some of the plurality of first magnetic sensors included in the magnetic sensor array 211 (e.g., the first magnetic sensor 2111, the first magnetic sensor 2112, the first magnetic sensor 2113, the first magnetic sensor 2114, the first magnetic sensor 2115, the first magnetic sensor 2116, or the like) have an unequal spacing between two adjacent first magnetic sensors (which are in non-uniform arrangement). For example, the spacing of the first magnetic sensors 2111 and the first magnetic sensors 2115 is equal to the spacing of the first magnetic sensors 2115 and the first magnetic sensors 2116. The spacing of first magnetic sensor 2111 and the first magnetic sensor 2112, is unequal to the spacing of the first magnetic sensor 2112 and the first magnetic sensor 2113. The spacing of the first magnetic sensor 2111 and the first magnetic sensor 2113 is unequal to the spacing of the first magnetic sensor 2113 and the first magnetic sensor 2114. Based on the non-uniformly arranged magnetic sensor array 211 described in the above example, the magnetic sensor array 211 may be divided into a region where the first magnetic sensors are relatively dense (e.g., the region where the first magnetic sensor 2112, the first magnetic sensor 2113, and the first magnetic sensor 2114 are located in FIG. 5C) and where the first magnetic sensors are relatively sparse (e.g., the region where the first magnetic sensor 2115 is located in FIG. 5C). Further, when covering the region of interest using the magnetic sensor array 211, the region where the first magnetic sensors are relatively dense (also referred to as a dense region) may cover the region of interest, and the region where the first magnetic sensors are relatively sparse (also referred to as a sparse region) may cover a region surrounding the region of interest. For example, if the region of interest is the ankle, then the dense region described above may be covered over the ankle, and the sparse region described above may be covered over the leg or the top of the foot, etc. around the ankle. With such arrangement, the region of interest (e.g., ankle) may be covered with a plurality of first magnetic sensors, allowing the nuclear spin magnetic field signal of the region of interest to be fully and accurately acquired. And the nuclear spin magnetic field signals in the region surrounding the region of interest are relatively unimportant and may be acquired by a small number of first magnetic sensors. Based on this arrangement, the count of the first magnetic sensors in the magnetic sensor array is reduced to lower the cost of the hardware while guaranteeing the acquisition of the nuclear spin magnetic field signals in the region of interest.

It should be noted that only some of the first magnetic sensors are numbered in FIG. 2, FIG. 5A, FIG. 5B, and FIG. 5C. The other ones in the figure indicated by the small rectangular boxes are also first magnetic sensors contained in the magnetic sensor array.

In some embodiments, the number (or count) and/or layout of first magnetic sensors of the magnetic sensor array 211 is determined based on the region of interest.

The count of first magnetic sensors of the magnetic sensor array 211 correlates with the size of the region of interest and/or the shape of the region of interest.

In some embodiments, the count of first magnetic sensors of the magnetic sensor array 211 is smaller if the region of interest is a relatively regularly shaped part, and the count of first magnetic sensors of the magnetic sensor array 211 is larger if the region of interest is a relatively irregularly shaped part. For example, if the region of interest is the abdomen, which is a relatively regular shape, the count of first magnetic sensors of the magnetic sensor array 211 may be 20. As another example, if the region of interest is a knee, the knee is a joint with a relatively irregular shape, the count of first magnetic sensors of the magnetic sensor array 211 may be 50.

In some embodiments, if the volume of the region of interest is large, the count of first magnetic sensors of the magnetic sensor array 211 is relatively large. If the volume of the region of interest is small, the count of first magnetic sensors is relatively small. For example, if the region of interest is the abdomen, the abdomen is large, the count of first magnetic sensors of the magnetic sensor array 211 may be 50. As another example, if the region of interest is the elbow, and the volume of the elbow is small in relation to the abdomen, the count of first magnetic sensors of the magnetic sensor array 211 is correspondingly small, e.g., the count of first magnetic sensors of the magnetic sensor array 211 may be 10.

In some embodiments, the count of first magnetic sensors of the magnetic sensor array 211 may be determined based on a combination of the shape and volume of the region of interest. For example, a shape score and a volume score for each region of interest may be predetermined. The shape score for a region of interest that has a relatively regular shape is a first shape score, a shape score for a region of interest that has a relatively irregular shape is a second shape score, the first shape score is less than the second shape score. For example, the first shape score is 10 and the second shape score is 20. The volume score is related to the volume of the region of interest. The larger the volume of the region of interest, the higher the volume score. For example, the volume score of the elbow is 10, the volume score of the knee is 15, the volume score of the abdomen is 30, etc. Based on this, the count of first magnetic sensors may be determined based on the shape score and the volume score. For example, the count of first magnetic sensors may be equal to the sum of the shape score and the volume score of the region of interest. In some embodiments, the shape score and/or volume score of each region of interest may be set by the system by default or by a user.

In some embodiments, the processing device determines the count of first magnetic sensors of the magnetic sensor array based on the region of interest and object information using a trained quantity determination model. For example, an input of the quantity determination model is the region of interest and the object information and the output of the quantity determination model is the count of first magnetic sensors. The quantity determination model is a machine learning model. The object information reflects a physiological characteristic of the object, for example, the object information may include the gender, the age, the height, the weight, the body fat percentage, or the like of the object.

It is noted that the MRI system (e.g., the MRI device 140) may be adapted to have a plurality of signal receiving assemblies, and each signal receiving assembly having a different count of first magnetic sensors. In some embodiments, before imaging the object using the MRI system, a user of the MRI device 140 may utilize the quantity determination model to determine a corresponding count of sensors based on the current region of interest of the object and configure a signal receiving assembly having the count of first magnetic sensors of the signal receiving assembly within the MRI system to accomplish imaging of the object.

The quantity determination model may be obtained by training an initial quantity determination model based on first sample data. For example, the first sample data includes a plurality of groups of first sample data and each group may include sample regions of interest and sample object information. A label (referred to as a first label) of each of the groups of first sample data is a count of sample sensors. The first sample data may be obtained based on a region of interest and object information of a historical imaging process, and the first label may be obtained by manual labeling based on a count of sensors used in the historical imaging process. The training process includes taking the first sample data as an input to the initial quantity determination model, determining a value of a first loss function based on an output of the initial quantity determination model and the first label, and iteratively training the initial quantity determination model until a predetermined condition is satisfied (e.g., the first loss function is less than a first predetermined loss threshold, or the number of iterations is greater than or equal to a first predetermined number of iterations), obtaining the trained quantity determination model.

The quantity determination model may include a convolutional neural network (CNN), a deep neural network (DNN), a fully connected neural network (FCN), etc., which is not limited in the present disclosure.

In some embodiments, if the region of interest is a relatively regularly shaped part, the plurality of first magnetic sensors contained in the magnetic sensor array 211 are arranged uniformly. If the region of interest is a relatively irregularly shaped part, the plurality of first magnetic sensors are non-uniformly arranged. Merely by way of example, if the region of interest is the abdomen, and the abdomen is a relatively regular shape, the layout of the plurality of first magnetic sensors in the magnetic sensor array 211 may be arranged uniformly. Merely by way of example, if the region of interest is the knee, and the shape of the knee is relatively irregular, the layout of the plurality of first magnetic sensors in the magnetic sensor array 211 may be non-uniformly arranged. For example, a spacing of two adjacent first magnetic sensors in a region of the magnetic sensor array 211 that covers the knee (the first magnetic sensors are arranged densely) is small, and a spacing of two adjacent first magnetic sensors in a region of the magnetic sensor array 211 that covers the leg around the knee (the first magnetic sensors are arranged sparsely) is large.

In some embodiments, the plurality of first magnetic sensors contained in the magnetic sensor array 211 are uniformly arranged if the volume of the region of interest is large, and the plurality of first magnetic sensors contained in the magnetic sensor array 211 are non-uniformly arranged. If the region of interest is small, the plurality of first magnetic sensors contained in the magnetic sensor array 211 are arranged non-uniformly. Merely by way of example, if the region of interest is the abdomen, and the volume of the abdomen is large, the plurality of first magnetic sensors contained in the magnetic sensor array 211 are uniformly arranged. Merely by way of example, if the region of interest is the elbow, and the elbow is relatively small, the plurality of first magnetic sensors contained in the magnetic sensor array 211 are non-uniformly arranged.

In some embodiments, the layout of the magnetic sensor array 211 may be determined based on a combination of the shape and volume of the region of interest. Following the previous example, the layout may be determined based on the shape score and the volume score, for example, the score sum (the sum of the shape score and the volume score) may be compared to a predetermined score threshold. If the score sum is less than the score threshold, the plurality of first magnetic sensors of the magnetic sensor array is uniformly arranged, and vice versa, and if the score sum is greater than the score threshold, the plurality of first magnetic sensors of the magnetic sensor array is non-uniformly arranged.

In some embodiments, the magnetic sensor array may include a plurality of magnetic sensor sub-arrays, and each magnetic sensor sub-array may include one or more first magnetic sensors. The first magnetic sensors in each magnetic sensor sub-array may be uniformly arranged or non-uniformly arranged, and the plurality of magnetic sensor sub-arrays may be spliced to form the magnetic sensor array. In some embodiments, one or more magnetic sensor sub-arrays may be selected to be spliced into a target magnetic sensor array based on information such as the size, the shape, and other information of a region of interest of a current object. The target magnetic sensor array is used to receive a nuclear spin magnetic field signal of the current object. For example, the plurality of magnetic sensor sub-arrays may be separately fixed to a plurality of sub-carriers, and when splicing of the plurality of magnetic sensor sub-arrays is required, a user of the MRI system (e.g., the MRI device 140) may splice (e.g., via a clasp) the plurality of sub-carriers to accomplish splicing of the plurality of magnetic sensor sub-arrays.

The layout of the magnetic sensor sub-arrays may be determined based on the shape of the covered region. For example, in the case where the region of interest is the leg (including the knee), since the shape of the knee is relatively irregular and the shape of the other regions of the leg other than the knee is relatively regular, the magnetic sensor sub-arrays covering the kneecap may be uniformly arranged and the magnetic sensor sub-arrays covering the other regions of the leg may be non-uniformly arranged. For example, the plurality of first magnetic sensors in the magnetic sensor sub-arrays covering the knee are densely and uniformly arranged, and the plurality of first magnetic sensors in the magnetic sensor sub-arrays covering the other regions of the leg are more sparsely distributed and non-uniformly arranged. In other words, a magnetic sensor array used for scanning the knee consists of a uniformly arranged magnetic sensor sub-array connected with a non-uniformly arranged magnetic sensor sub-array. The magnetic sensor array is non-uniformly arranged.

In some embodiments, the processing device determines the layout of the magnetic sensor array based on the region of interest and the object information using a trained layout determination model. For example, an input of the layout determination model is the region of interest and the object information, and an output of the layout determination model is a layout type of the magnetic sensor array. The layout determination model is a machine learning model.

It is noted that the MRI system (e.g., the MRI device 140) may be adapted to have a plurality of signal receiving assemblies, and each of the signal receiving assemblies has a different layout of the magnetic sensor array. In some embodiments, before imaging the object using the MRI system, the user of the MRI device 140 may, based on the region of interest and the object information, determine the layout of the magnetic sensor array utilizing the trained layout determination model and configure a signal receiving assembly having the layout within the MRI system for accomplishing imaging of the object.

The layout determination model may be obtained by training an initial layout determination model based on second sample data. For example, the second sample data includes a plurality of groups of second sample data and each group may include sample regions of interest and sample object information. A label (referred to as a second label) of each of the groups of second sample data is a sample layout. The second sample data may be obtained based on a region of interest and object information of the historical imaging process, and the second label may be obtained based on manual labeling of the magnetic sensor array layout used in the historical imaging process. The training process includes taking the second sample data as an input to the initial layout determination model, determining a value of a second loss function based on an output of the initial layout determination model with the second label, and iteratively training the initial layout determination model until a predetermined condition is satisfied (e.g., the second loss function is less than a second predetermined loss threshold or the number of iterations is greater than or equal to a second predetermined number of iterations), obtaining the trained layout determination model.

The layout determination model may include a convolutional neural network (CNN), a deep neural network (DNN), a fully connected neural network (FCN), etc., which is not limited in the present disclosure.

Whether the shape of each region of interest is regular may be preset, e.g., the chest, abdomen, legs, and arms may be preset to be relatively regular in shape, and the elbows, knees, and face may be preset to be relatively irregular in shape.

In some embodiments of the present disclosure, by non-uniformly arranging the first magnetic sensors in the magnetic sensor array, the scanning effect of the region of interest may be safeguarded, so that the acquired signal information related to the region of interest is more accurate and detailed. By setting the layout of the first magnetic sensors according to the region of interest, the adaptability of the arrangement of the first magnetic sensor to the region of interest may be improved. By setting the count of first magnetic sensors according to the region of interest, not only the scanning effect of the region of interest is guaranteed, but also the count of first magnetic sensors to be used is reduced, thus reducing the cost of the MRI device.

In some embodiments, the magnetic sensor array 211 is also configured to monitor physiological information of the object.

The physiological information refers to information reflecting the bioelectrical characteristics of the object's body. The physiological information may be electrocardiographic information, brainwave information, electromyographic information, respiratory information, or the like, of the object. The electrocardiogramnformation may be characterized based on the electrocardiogramrent value or the electrocardiogramtial value. The electromyographic information may be characterized based on the electromyographic current value or the electromyographic potential value.

In some embodiments, during the MRI of the object, a data processor (e.g., the processing device 110) may determine the physiological information of the object based on a nuclear spin magnetic field signal acquired by the magnetic sensor array 211. For example, a cross-reference table of the mapping relationship between the nuclear spin magnetic field signal and the electrocardiogramnformation may be preset, and the corresponding electrocardiogramformation may be obtained by looking up the table based on the nuclear spin magnetic field signal acquired by the magnetic sensor array 211.

Some embodiments of the present disclosure extend the field of application of the magnetic sensors by monitoring the physiological information of the object by the magnetic sensor arrays, thereby expanding the types of functionalities of the magnetic sensor array configured in the MRI system.

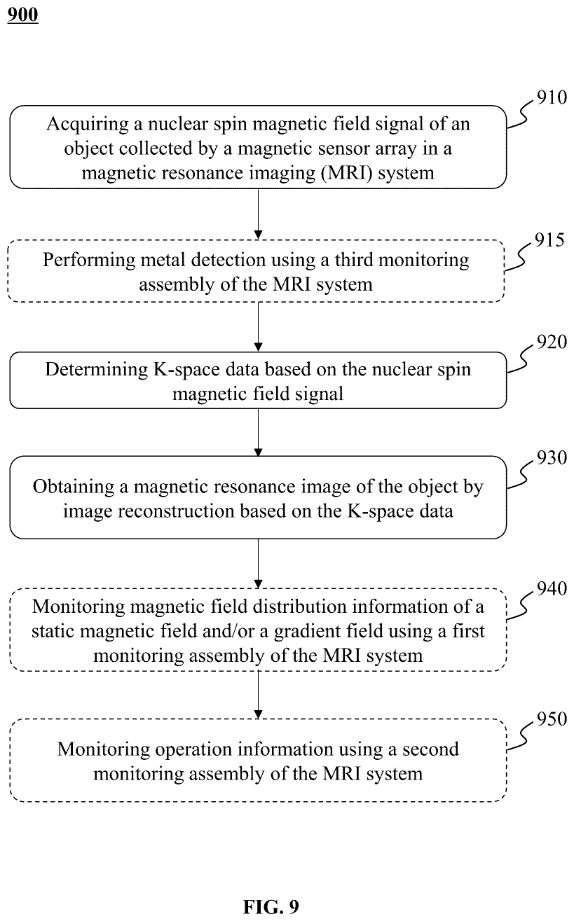

In some embodiments, the MRI device 140 may further include a data processor. The data processor is configured to generate a magnetic resonance image of the object based on the nuclear spin magnetic field signal. For example, the data processor may determine K-space data based on the nuclear spin magnetic field signal of the object and obtain, based on the K-space data, the magnetic resonance image of the object by image reconstruction. More descriptions regarding generating the magnetic resonance image of the object may be found in FIG. 9 and its related descriptions.

In some embodiments of the present disclosure, by using the signal receiving assembly to acquire the nuclear spin magnetic field signal of the object, the nuclear spin magnetic field signal reception, as compared to the nuclear spin magnetic field signal reception via an RF receiving coil, gets rid of the dependence on static and gradient magnetic fields in the reception process and reduces the magnet and gradient coil operation time, thereby saving the operating cost of the MRI system. Because of the small size of the magnetic sensor, a larger number of channels may be set up, which not only overcomes the problem of the limited number of channels of the RF receiving coil, thus capturing more information in the region of interest, but also may be applied to different scanning sites, broadening the application scope of magnetic resonance scanning.

In some embodiments, the MRI device 140 further includes a first monitoring assembly.

The first monitoring assembly includes at least one second magnetic sensor. The first monitoring assembly is configured to monitor distribution information of a magnetic field (e.g., the static magnetic field and/or the gradient magnetic field). In some embodiments, the first monitoring assembly may include only one second magnetic sensor. The only one second magnetic sensor is configured to simultaneously monitor the distribution information of the static magnetic field and the gradient magnetic field. In some embodiments, a magnetic sensor group consisting of a plurality of second magnetic sensors, the first monitoring assembly may include a magnetic sensor group consisting of a plurality of second magnetic sensors. The plurality of second magnetic sensors is configured to monitor the magnetic field distribution information of the static magnetic field and the gradient magnetic field. As another example, the first monitoring assembly includes two sets of magnetic sensors, each set of magnetic sensors includes at least one second magnetic sensor, one set of the two sets of magnetic sensors is configured to monitor the distribution information of the static magnetic field, and another set of magnetic sensors is configured to monitor the distribution information of the gradient magnetic field.

In some embodiments, when the first monitoring assembly includes a plurality of second magnetic sensors, the plurality of second magnetic sensors are located at different locations of the MRI system, and the plurality of second magnetic sensors may be linearly arranged or non-linearly arranged. The plurality of second magnetic sensors linearly arranged means that the plurality of second magnetic sensors are located in the same straight line. The plurality of second magnetic sensors non-linearly arranged means that at least two of the plurality of second magnetic sensors are located on different straight lines, or on the same curve.

The static magnetic field refers to a magnetic field generated by a magnet assembly in the MRI device. The static magnetic field is uniformly distributed in the scanning aperture of the MRI device (i.e., the magnetic induction strength of the magnetic field at any location in the scanning aperture is the same). For example, the magnetic induction strength of the static magnetic field may be 0.55 T, 0.3 T, 0.065 T, 1.5 T, 3 T, 6 T, or the like.

In some embodiments, the magnet assembly in the MRI device may be an ultra-low-field magnet assembly, and the static magnetic field is generated by the ultra-low-field magnet assembly, and the static magnetic field is an ultra-low field (e.g., 0.55 T, 0.3 T, 0.065 T, etc.). The ultra-low-field magnet assembly refers to a magnet assembly capable of generating an ultra-low field. The ultra-low field is a static magnetic field with magnetic induction strength is lower than an ultra-low field threshold, and the ultra-low field threshold may be 0.6 T, 0.5 T, etc.

In some embodiments, the static magnetic field is a variable magnetic field, and variable magnetic field refers to a magnetic field with the magnetic induction strength being variable over time (e.g., switching between a plurality of discrete values, or switching within a continuous range of values). For example, the magnetic induction strength of the static magnetic field may be variable over time within a range of [0.5 T, 0.7 T], [0.4 T, 0.8 T], [0.3 T, 1 T], [0.25 T, 2 T], [0.1 T, 3 T], [0.2 T, 2.5 T], or the like.

The gradient magnetic field refers to a magnetic field generated by a gradient coil assembly in the MRI device. The magnetic induction strength of the gradient magnetic field is varying from location to location in the scanning aperture. The gradient magnetic field is a magnetic field that is linearly distributed in space.

FIG. 6 is a schematic diagram illustrating a magnetic resonance imaging system according to other embodiments of the present disclosure.

As shown in FIG. 6, in some embodiments, the gradient coil assembly may generate one or more magnetic field gradient pulses in the X-direction (Gx), the Y-direction (Gy), and the Z-direction (Gz) for the primary magnetic field to encode spatial information of the object. In some embodiments, the X-direction may be designated as a frequency-encoding direction, and the Y-direction may be designated as a phase-encoding direction. In some embodiments, Gx may be used for frequency encoding or signal readout, commonly referred to as a frequency encoding gradient or a readout (RO) gradient. In some embodiments, Gy may be used for phase encoding, referred to as a phase-encoding (PE) gradient. In some embodiments, Gz may be used for slice selection to obtain two-dimensional K-space data, often referred to as a selected layer (SS) gradient. In some embodiments, Gz may be used for phase encoding to obtain three-dimensional K-space data.

The distribution information of a magnetic field (also referred to as magnetic field distribution information) refers to data reflecting the distribution of the magnetic field (e.g., a static or gradient magnetic field). The magnetic field distribution information includes at least one of a temporal distribution or a spatial distribution.

The temporal distribution refers to data reflecting the value of the magnetic induction strength of the static or gradient magnetic field over an imaging time. The imaging time refers to the amount of time it takes for the MRI device to complete the imaging process of the object. The imaging time may be preset based on experience, for example, the imaging time may be 2 minutes.

The temporal distribution of the static magnetic field may be characterized based on a temporal distribution vector of the static magnetic field. For example, the temporal distribution of the static magnetic field characterized by the temporal distribution vector may be (3, 3, 3, 2.99, 3, . . . ), which means that the magnetic induction strength of the static magnetic field is 3 T, 3 T, 3 T, 2.99 T, 3 T, . . . , respectively at the various observation time points within the imaging time. The time interval between two adjacent observation time points may be preset, e.g., the above time interval may be 0.1 s.

The temporal distribution of the gradient magnetic field may be characterized based on a temporal distribution matrix of the gradient magnetic field. Exemplarily, the temporal distribution of the gradient magnetic field characterized by the temporal distribution matrix may be shown in the following matrix A:

$$A = ( \begin{matrix}20 & 20 & 19.99 & 20 & 20 & 20.01 & … \\ 20 & 20 & 20 & 20.01 & 20.01 & 20 & … \\ 30 & 30 & 30 & 30 & 29.99 & 30 & …\end{matrix} ) .$$

Elements in the first row of matrix A characterize the gradient strengths in the X-direction at the various observation time points within the imaging time as 20 mT/m, 20 mT/m, 19.99 mT/m, 20 mT/m, 20 mT/m, 20 mT/m, 20.01 mT/m, Elements in the second row characterize the gradient strengths in the Y-direction at the various observation time points within the imaging time as 20 mT/m, 20 mT/m, 20 mT/m, 20.01 mT/m, 20.01 mT/m, 20 mT/m,. Elements in the third row characterize the gradient strengths in the Z-direction at various observation time points within the imaging time as 30 mT/m, 30 mT/m, 30 mT/m, 30 mT/m, 29.99 mT/m, 30 mT/m, . . . .

The spatial distribution reflects the distribution of the magnetic field in space (e.g., the scanning aperture of the MRI device).

Since the static magnetic field is uniformly distributed in space and the direction is fixed (e.g., uniformly distributed along the Z-axis direction in FIG. 7), the spatial distribution of the static magnetic field may be directly characterized based on the value of the magnetic induction strength of the static magnetic field, for example, may be 3 T.

It should be noted that the first monitoring assembly may only monitor the static magnetic field in a portion of the space within the scanning aperture that is away from the magnet assembly, as the magnetic field signal in the space close to the magnet assembly tends to saturate. However, since the static magnetic field is spatially uniformly distributed, the spatial distribution of the static magnetic field in a portion of the space characterizes the spatial distribution of the entire space within the scanning aperture.

The spatial distribution of the gradient magnetic field may be characterized based on the gradient strength of the gradient magnetic field. For example, the spatial distribution of the gradient magnetic field may be that the gradient strength in the X-direction is 20 mT/m (i.e., for every 1-meter change of the spatial coordinate in the X-direction, the gradient strength of the gradient magnetic field changes by 20 mT), the gradient strength in the Y-direction is 20 mT/m (i.e., for every 1-meter change of the spatial coordinate in the Y-direction, the gradient strength of the gradient magnetic field changes by 20 mT), and the gradient strength in the Z direction is 30 mT/m (i.e., for every 1-meter change of the spatial coordinates in the Z direction, the gradient strength of the gradient magnetic field changes by 30 mT). For another example, the spatial distribution of the gradient magnetic field may be that the gradient strength in the X-direction is 40 mT/m (i.e., for every 1-meter change of the spatial coordinate in the X-direction, the gradient strength of the gradient magnetic field changes by 40 mT), the gradient strength in the Y-direction is 40 mT/m (i.e., for every 1-meter change of the spatial coordinate in the Y-direction, the gradient strength of the gradient magnetic field changes by 40 mT), and the gradient strength in the Z direction is 50 mT/m (i.e., for every 1-meter change of the spatial coordinates in the Z direction, the gradient strength of the gradient magnetic field changes by 50 mT).

In some embodiments, the spatial distribution of the gradient magnetic field may be data in the form of vectors, e.g., the vector corresponding to the spatial distribution of the gradient magnetic field in the above example may be (20, 20, 30).

The second magnetic sensor is a sensing device capable of sensing the magnetic field information (e.g., the magnetic induction strength of the static magnetic field or the gradient magnetic field) and altering its electrical resistance based on changes in the magnetic field. For example, the second magnetic sensor may be a TMR sensor, a graphene sensor, a Hall sensor, or the like. In some embodiments, the second magnetic sensor is the TMR sensor. The second magnetic sensor may be the same as or similar to the first magnetic sensor.

In some embodiments, when measuring the spatial distribution of the static magnetic field using the TMR sensor as the second magnetic sensor, the second magnetic sensor may be used to measure the spatial distribution of a position has a distance from the static magnetic field within a preset threshold (e.g., 5 cm, 8 cm, 10 cm, 12 cm, 15 cm, 20 cm, etc. from the static magnetic field), to improve measurement accuracy. In some embodiments, when measuring the spatial distribution of the gradient magnetic field using the TMR sensor as the second magnetic sensor, the measurement may be performed when the static magnetic field is turned off, to improve measurement accuracy.

In some embodiments, a detection range of at least one of the second magnetic sensors in the first monitoring assembly covers an examination region of the MRI system. In conjunction with the foregoing, the examination region may be a region covered by the scanning aperture of the MRI device (e.g., the MRI device 143) or a portion of the scanning aperture (e.g., one-third of the scanning aperture, three-quarter of the scanning aperture, etc.). For example, the at least one second magnetic sensor in the first monitoring assembly may be linearly arranged along the axis of the scanning aperture to cover the examination region described above. In some embodiments, the at least one second magnetic sensor in the first monitoring assembly is disposed at different locations of the scanning aperture.

For example, as shown in FIG. 6, the first monitoring assembly may include six second magnetic sensors (including a second magnetic sensor 661, a second magnetic sensor 662, a second magnetic sensor 663, a second magnetic sensor 664, a second magnetic sensor 665, and a second magnetic sensor 666), and each of the six second magnetic sensors is disposed at two ends of the inner wall of the scanning aperture 1431 and/or in a region between the two ends of the scanning aperture 1431. Specifically, as shown in FIG. 6, the second magnetic sensor 661 and the second magnetic sensor 662 are disposed at the front end and the rear end, respectively, of the inner wall of the scanning aperture 1431, the second magnetic sensor 664 and the second magnetic sensor 666 are located on the left side of the inner wall of the scanning aperture 1431, and the second magnetic sensor 663 and the second magnetic sensor 665 are located on the right side of the inner wall of the scanning aperture 1431. The front end of the scanning aperture 1431 refers to the side where the entrance of the scanning aperture is located, and the rear end refers to the side opposite the entrance. The left side of the scanning aperture 1431 refers to the side corresponding to the positive direction of the X-axis, and the right side refers to the side corresponding to the negative direction of the X-axis.

In some embodiments, one or more of the second magnetic sensor 663, the second magnetic sensor 664, the second magnetic sensor 665, and the second magnetic sensor 666, may be disposed on a circumference formed with the center point of the effective length of the central axis 651. In some embodiments, the circumference may be on a circumference formed with a point at ¼, ¾, ⅓, ⅔, ⅗, ⅖, or ⅘ of the effective length of the central axis 651 as the center. The effective length of the central axis 651 refers to the distance from the entrance of the scanning aperture 1431 to the rear end.

In some embodiments, the first monitoring assembly may include one or more groups of second magnetic sensors (e.g., 2, 4, 6, etc.). Each group of second magnetic sensors includes at least two second magnetic sensors (e.g., 2 or 3 or 4, etc.). The groups of second magnetic sensors may be disposed on the two ends and/or the region between the two ends of the inner wall of the scanning aperture 1431, respectively.

In some embodiments, a second magnetic sensor may be provided on the outer surface of a frame (e.g., frame 1432) or embedded in an inner wall of the frame. For example, the inner wall of the frame may be provided with a groove, the second magnetic sensor may be mounted in the groove, and the outer surface of the second magnetic sensor (the side facing the scanning aperture) may be flat with the inner wall surface or a certain height (e.g., 1 mm) above the inner wall surface. Further, the groove may be provided with a top cover. The top cover may be opened when the second magnetic sensor is being used to enable the second magnetic sensor to monitor the magnetic field distribution information of the static magnetic field and/or the gradient magnetic field. The top cover may be closed when the second magnetic sensor is not used and the closed top cover may be used to weaken the mutual interference between the second magnetic sensor and the other components (e.g., the gradient coil).

In some embodiments, different second magnetic sensors in the first monitoring assembly may be used to monitor the static magnetic field and the gradient magnetic field, respectively. A second magnetic sensor for monitoring the static magnetic field has a different measurement accuracy and/or a different sampling rate relative to a second magnetic sensor for monitoring the gradient magnetic field.

It should be noted that the monitoring of the static magnetic field requires high monitoring accuracy and low sampling rate (i.e., requiring the magnetic sensor to be sensitive to direct current), therefore, the static magnetic field may be monitored using a high-precision, low-sampling-rate magnetic sensor. The monitoring of the gradient magnetic field requires a high response time (i.e., requiring the magnetic sensor to be sensitive to alternating current), and therefore, the gradient magnetic field may be monitored using a magnetic sensor with a high sampling rate. The response time refers to a time between the moment when the gradient magnetic field changes and the moment when the change is monitored by the first monitoring assembly. Accordingly, the second magnetic sensor monitoring the static magnetic field has a higher monitoring accuracy than the second magnetic sensor monitoring the gradient magnetic field, and the second magnetic sensor monitoring the static magnetic field has a lower sampling rate than the second magnetic sensor monitoring the gradient magnetic field.

In some embodiments of the present disclosure, more accurate monitoring data may be obtained by monitoring the static magnetic field and the gradient magnetic field, respectively, using second magnetic sensors with different measurement accuracies and/or different sampling rates.

In some embodiments, the first monitoring assembly includes at least one movable second magnetic sensor. For example, among the six second magnetic sensors shown in FIG. 6, the second magnetic sensor 663, the second magnetic sensor 664, the second magnetic sensor 665, and the second magnetic sensor 666 are movable second magnetic sensors. As another example, all the second magnetic sensors in the first monitoring assembly are movable second magnetic sensors. As yet another example, the first monitoring assembly includes only one second magnetic sensor, and the second magnetic sensor is movable. For example, the movable second magnetic sensor is mounted at the top center of the inner wall of the scanning aperture 1431 of the MRI device 143 and is movable back and forth along the central axis 651 of the scanning aperture 1431, movable in a radial plane (e.g., the plane in which the X-axis and the Y-axis are located) that is perpendicular to the central axis 651, and/or is rotatable around the central axis 651.

In some embodiments, the at least one movable second magnetic sensor may be moved along an axial direction (e.g., the Z-direction shown in FIG. 6) or a circumferential direction (e.g., the X-direction or the Y-direction shown in FIG. 6) of the scanning aperture of the MRI device, and the movement may include rotating (e.g., rotating within a range of 0° to 360°), translating (e.g., up and down, forward and backward, side to side, etc.), or the like. As shown in FIG. 6, for example, the second magnetic sensor 663, the second magnetic sensor 664, the second magnetic sensor 665, and the second magnetic sensor 666 may translate along the axial direction (the Z-direction shown in FIG. 6, or the reverse of the Z-direction) of the scanning aperture 1431, and/or rotate around the center axis of the scanning aperture 1431, and/or move in a direction perpendicular to the axial direction (the Z-direction shown in FIG. 6, or the reverse of the Z-direction).

In some embodiments, a guide rail may be disposed within the groove, and the movable second magnetic sensor may be disposed on the guide rail to be able to move along the guide rail. In some embodiments, a mechanical arm may be provided within the groove, and the mechanical arm grips the movable second magnetic sensor. When the movable second magnetic sensor is not in use, the mechanical arm may be folded to retract the movable second magnetic sensor into the groove. When the movable second magnetic sensor is used, the mechanical arm may extend or be unfolded so that the movable second magnetic sensor extends out of the groove to acquire the nuclear spin magnetic field signal of the object, and the second magnetic sensor may be made to rotate or translate by rotation or movement of the mechanical arm.

In some embodiments, the count of the movable second magnetic sensors in the first monitoring assembly is less than a preset threshold.

The preset threshold may be a value greater than or equal to 1, such as 2, 3, 4, 5, 6, 8, or 12, etc. In some embodiments, the preset threshold is 6. For example, when the count of the movable second magnetic sensors is 6, in the process of monitoring the magnetic field distribution information of the static magnetic field by the second magnetic sensors, each of the movable second magnetic sensors are capable of acquiring two sets of data (transverse and longitudinal) at each of the 6 different positions, thereby obtaining 12 sets of data, and the data processor (e.g., the processing device 110) may, based on the above 12 sets of data, determine the magnetic field distribution information of the static magnetic field by calculating using a linear function. When the movable second magnetic sensor monitors the spatial and temporal distribution of the gradient magnetic field, the movable second magnetic sensor is capable of measuring magnetic field data of the 6 different positions at different time points to obtain the spatial and temporal distribution of the gradient magnetic field based on the magnetic field data of the 6 different positions at multiple time points. In some embodiments, the spatial and temporal distribution of the gradient magnetic field and the spatial or temporal distribution of the static magnetic field may be implemented in any feasible way based on measured magnetic field data, which is not limited in the present disclosure.

In some embodiments of the present disclosure, the occupancy of space within the scanning aperture by the first monitoring assembly may be reduced by setting the at least one second magnetic sensor of the first monitoring assembly on the outer surface of the frame or embedding the at least one second magnetic sensor in the inner wall of the frame. By setting at least a portion of the at least one second magnetic sensor to move, it is possible for a small number of second magnetic sensors to accomplish the monitoring of the entire static magnetic field and/or gradient magnetic field, which safeguards the monitoring accuracy of the magnetic field distribution information of the static magnetic field and/or gradient magnetic field while reducing the cost, and also avoiding the influence of the first monitoring assembly on the scanning imaging process of the MRI system. The cost of the device may be further reduced by limiting the count of the movable second magnetic sensors.

In some embodiments of the present disclosure, utilizing at least one second magnetic sensor to monitor the spatial distribution and temporal distribution of the static magnetic field and the gradient magnetic field in real-time may enhance the efficacy of the MRI and the quality of the imaging results, and make the electronics and structural logic of the MRI system simple, which reduces the production cost of the MRI system and strengthens the universality of the usage scenario of the MRI system. By configuring at least one second magnetic sensor to cover the examination region of the MRI system, the accuracy of the second magnetic sensor in monitoring the magnetic field distribution information of the static magnetic field and/or the gradient magnetic field may be improved.

In some embodiments, the MRI device 140 further includes a second monitoring assembly.

The second monitoring assembly includes one or more third magnetic sensors. The second monitoring assembly is configured to monitor operation information of the MRI device. In some embodiments, when the second monitoring assembly includes a plurality of third magnetic sensors, the plurality of third magnetic sensors are located at different locations of the MRI device 140, and the plurality of third magnetic sensors may be arranged linearly (e.g., the plurality of third magnetic sensors are located on the same straight line) or non-linearly (e.g., at least two of the plurality of third magnetic sensors are located on different straight lines, or located on the same curve).

The third magnetic sensor is a sensing device capable of sensing the magnetic field information (e.g., the magnetic induction strength of the static magnetic field or the gradient magnetic field) and altering its electrical resistance based on changes in the magnetic field. For example, the third magnetic sensor may be a TMR sensor, a graphene sensor, a Hall sensor, or the like. In some embodiments, the third magnetic sensor is the TMR sensor. The third magnetic sensor may be the same as or similar to the first magnetic sensor or the second magnetic sensor.

The operation information of the MRI device includes at least magnetic field anomaly information and/or failure information of the MRI device.

The magnetic field anomaly information refers to information reflecting an anomaly in the magnetic induction strength of the magnetic field (e.g., the static magnetic field and/or the gradient magnetic field). The magnetic field anomaly information may indicate whether the static magnetic field is normal or abnormal and the gradient magnetic field is normal or abnormal. The abnormal magnetic field means that the magnetic induction strength of the static magnetic field is not in a normal range, or the gradient strength of the gradient magnetic field is not in a normal range. The normal range may be preset. For example, the normal range of the magnetic induction strength of the static magnetic field may be preset to [2 T, 6 T], and the normal range of the strength of the gradient strength of the gradient magnetic field may be preset to [10 T/m, 80 T/m]. Based on the normal range, for example, when the magnitude of the magnetic induction strength of the static magnetic field is 1.8 T (not within the normal range), the static magnetic field may be determined to be abnormal. As another example, when the gradient strength of the gradient magnetic field is 15 T/m (within the normal range), the gradient magnetic field is determined to be normal.

The failure information refers to information reflecting whether a magnet (e.g., one that generates the magnetic field) or a gradient coil has failed. The failure information may include magnet malfunction or non-malfunction, and gradient coil malfunction or non-malfunction. When the magnet malfunction is involved, the magnetic induction strength of the static magnetic field generated by the magnet assembly is lower than a preset ratio of a preset magnetic induction strength. For example, if the preset magnetic induction strength of the static magnetic field is 3 T and the preset ratio is 90%, assuming that the magnetic induction strength of the static magnetic field generated by the current magnet is 1.5 T (1.5 T/3 T×100%=50%<90%), the magnet malfunction involves. When the gradient coil malfunction is involved, a gradient strength of the gradient magnetic field generated by the gradient coil assembly is lower than a preset ratio of a preset gradient strength. For example, if the preset gradient strength of the gradient magnetic field is 20 T/m and the preset ratio is 90%, assuming that the gradient strength of the gradient magnetic field generated by the current gradient coil is 15 T/m ((15 T/m)/(20 T/m)×100%=75%<90%), the gradient coil malfunctions.

In some embodiments, the second monitoring assembly may be disposed anywhere on the surface of a scanning bed or the inner wall of the scanning aperture 1431. In some embodiments, the second monitoring assembly is provided at an edge of the scanning bed or at an edge of the scanning aperture (e.g., the scanning aperture 1431) of the MRI device (e.g., the MRI device 143).

FIG. 7 is a schematic diagram illustrating a magnetic resonance imaging system according to some other embodiments of the present disclosure.

As shown in FIG. 7, the second monitoring assembly includes five third magnetic sensors. A third magnetic sensor 761 and a third magnetic sensor 762 may be disposed at the edge of the scanning aperture 1431. A third magnetic sensor 763, a third magnetic sensor 764, and a third magnetic sensor 765 may be disposed at the edge of the scanning bed for monitoring the magnetic induction strength of the static magnetic field and/or the gradient magnetic field, thereby determining the magnetic field anomaly information or the failure information.

In some embodiments, the third magnetic sensor of the second monitoring assembly and the first magnetic sensor in the signal receiving assembly (e.g., signal receiving assembly 211) may have different types and/or different structures. For example, the third magnetic sensor is a TMR sensor, and the first magnetic sensor is a graphene sensor. As another example, the third magnetic sensor and the first magnetic sensor are both TMR sensors, but the third magnetic sensor has a different structure than the first magnetic sensor (e.g., the thickness of the free layer of the third magnetic sensor is different than the thickness of the free layer of the first magnetic sensor).

In some embodiments, the first monitoring assembly and the second monitoring assembly may be a single assembly, i.e., the MRI device 140 includes only the first monitoring assembly or the second monitoring assembly. That is, the magnetic field monitoring assembly includes one or more second magnetic sensors, and/or one or more third magnetic sensors, and the magnetic field monitoring assembly is configured to simultaneously monitor the magnetic field distribution information and the operation information of the MRI device 140. In such cases, a portion of the magnetic sensors of the first monitoring assembly or the second monitoring assembly is configured to monitor the magnetic field distribution information of the static magnetic field and/or gradient field, and the other portion of the magnetic sensors is configured to monitor the operation information of the MRI system. Alternatively, all magnetic sensors are configured to monitor the magnetic field distribution information of the static magnetic field and/or the gradient field and determine the operation information of the MRI system based on the magnetic field distribution information.

In some embodiments of the present disclosure, by providing the second monitoring assembly in the MRI system to monitor the operation information of the MRI system (e.g., the magnetic field anomaly information and/or the failure information), the normal operation of the MRI system may be safeguarded to avoid the system malfunction from affecting the scanning process, which improves the scanning efficiency. By setting the second monitoring assembly at the edge of the scanning bed or at the edge of the scanning aperture of the MRI device, operation information may be detected before the scanning, so that the operation state of the MRI system may be obtained in advance to respond to possible abnormalities or malfunctions on time. By setting the third magnetic sensor and the magnetic sensor of the signal receiving assembly (e.g., the first magnetic sensor) as different types of sensors or having different structures, it is possible to make the third magnetic sensor more sensitive to the static magnetic field and the gradient magnetic field and more suitable for monitoring the operation information of the MRI system. Whereas the magnetic sensor of the signal receiving assembly is more sensitive to nuclear spin magnetic field signals and more suitable for acquiring the nuclear spin magnetic field signal of the object, thus the accuracy of the third magnetic sensor for monitoring the operation information and the accuracy of the magnetic sensor of the signal receiving assembly for acquiring nuclear spin magnetic field signal are improved, i.e., the relevance and adaptability of the third magnetic sensor and the magnetic sensor of the signal receiving assembly are enhanced.

In some embodiments, the MRI device 140 further includes a third monitoring assembly.

The third monitoring assembly includes one or more fourth magnetic sensors. The third monitoring assembly is configured to perform metal detection. In some embodiments, when the third monitoring assembly includes a plurality of fourth magnetic sensors, the plurality of fourth magnetic sensors are located at different locations of the MRI device, and the plurality of fourth magnetic sensors may be arranged linearly (e.g., with the plurality of fourth magnetic sensors located on the same straight line) or non-linearly (e.g., with at least two of the plurality of fourth magnetic sensors located on different straight lines, or on the same curve).

The fourth magnetic sensor is a sensing device capable of sensing the magnetic field information (e.g., the magnetic induction strength of the static magnetic field or the gradient magnetic field) and altering its electrical resistance based on changes in the magnetic field. For example, the fourth magnetic sensor may be a TMR sensor, a graphene sensor, a Hall sensor, or the like. In some embodiments, the fourth magnetic sensor is the TMR sensor. The fourth magnetic sensor may be the same as or similar to the first magnetic sensor, the second magnetic sensor, or the third magnetic sensor.

Metal detection refers to a process of detecting the presence or absence of redundant metal in the monitoring region. The monitoring region includes at least a scanning bed, and one or more of the fourth magnetic sensors of the third monitoring assembly are disposed within the monitoring region to perform metal detection on the monitoring region. The redundant metal refers to a metal object that is not part of the MRI system (e.g., a stainless-steel cup) or contains metal (e.g., a physician's cell phone), as well as a metal object that the subject carries with (e.g., the patient's keys, metal jewelry worn, etc.). When the redundant metal is present in the monitoring region, the metal detection result is “yes”, and conversely, when redundant metal is not present in the monitoring region, the metal detection result is “no”.

In some embodiments, the third monitoring assembly within the monitoring region may be connected to an external circuit, and when a magnetic field generated by the redundant metal (e.g., a magnetic field generated by the redundant metal being magnetized by the static magnetic field or the gradient magnetic field) is present within the monitoring region as detected by one or more fourth magnetic sensors in the third monitoring assembly, a change in the resistance of the fourth magnetic sensors results in a change in the current of the external circuit, and the change may be monitored by a current monitoring device (e.g., an ammeter) in the external circuit to determine whether the redundant metal is present in the monitoring region (yes if the current changes, no if it does not).

In some embodiments, the third monitoring assembly may be disposed within a scanning room. For example, one or more fourth magnetic sensors in the third monitoring assembly may be disposed in the ceiling, the floor, or the wall of the scanning room.

In some embodiments, the third monitoring assembly may be provided on a frame of the MRI device. For example, one or more fourth magnetic sensors of the third monitoring assembly may be provided on an inner or outer side of a housing of the frame 1432 of the MRI device 143.

In some embodiments, the third monitoring assembly may be disposed anywhere on the scanning bed (e.g., the scanning bed 141). In some embodiments, the third monitoring assembly may be disposed at the edge of the scanning bed. As shown in FIG. 7, one or more fourth magnetic sensors (e.g., the fourth magnetic sensor 766) in the third monitoring assembly may be disposed on a side of the scanning bed 141 away from the scanning aperture 1431.

In some embodiments of the present disclosure, by providing the third monitoring assembly for metal detection, the influence of redundant metal on the scanning process may be avoided, and the effectiveness of the scanning may be ensured.

In some embodiments, the second monitoring assembly and the third monitoring assembly may be a single assembly to monitor the operation information and perform metal detection simultaneously. That is, one or more third magnetic sensors and/or one or more fourth magnetic sensors form a device monitoring assembly, and the device monitoring assembly is configured to monitor the operation information of the MRI device 140 and perform the metal detection simultaneously.

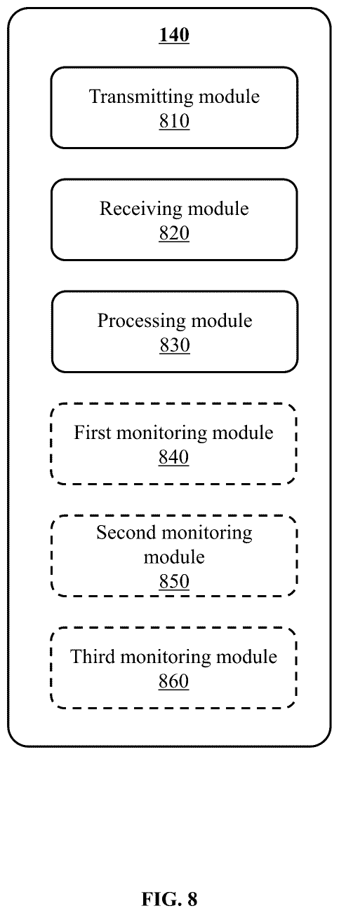

FIG. 8 is a schematic diagram illustrating modules of a magnetic resonance imaging system according to some embodiments of the present disclosure. In some embodiments, as shown in FIG. 8, the MRI device 140 may include a transmitting module 810, a receiving module 820, and a processing module 830.

The transmitting module 810 is configured to transmit an RF signal to an object. The transmitting module 810 may include an RF transmitting coil (e.g., an RF transmitting coil 630), and the RF signal refers to an RF pulsed magnetic field signal emitted by the RF transmitting coil. For example, the transmitting module 810 may include a coil holder and an RF transmitting coil configured to support the coil holder. The coil holder may be mounted to a frame (e.g., the frame 1432) of the MRI device (e.g., the MRI device 143). As another example, the transmitting module 810, after receiving a transmit command, may control the RF transmitting coil to transmit the RF signal (e.g., the RF pulse).

The receiving module 820 includes a signal receiving assembly (e.g., the signal receiving assembly 211) for acquiring the nuclear spin magnetic field signal of the object. More descriptions regarding the signal reception assembly may be found in FIG. 2 and its related descriptions.

The processing module 830 includes a data processor (e.g., the processing device 110) for generating a magnetic resonance image of the object based on the nuclear spin magnetic field signal. More descriptions regarding generating the magnetic resonance image of the object may be found in FIG. 9 and its related descriptions.

The first monitoring module 840 includes a first monitoring assembly for monitoring the magnetic field distribution information of the static magnetic field and/or the gradient magnetic field. More descriptions regarding the first monitoring assembly may be found in FIG. 2, FIG. 6, and their related descriptions.

The second monitoring module 850 includes a second monitoring assembly for monitoring the operation information. More descriptions regarding the second monitoring assembly may be found in FIG. 2, FIG. 7, and their related descriptions.

The third monitoring module 860 includes a third monitoring assembly for performing the metal detection. More descriptions regarding the third monitoring assembly may be found in FIG. 2, FIG. 7, and their related descriptions.

It is to be noted that the above description of the MRI device 140 and its modules is provided only for descriptive convenience and does not limit the present disclosure to the scope of the cited embodiments. It is to be understood that, for a person skilled in the art, with an understanding of the principle of the system, it may be possible to arbitrarily combine modules or form subsystems that are connected to other modules without departing from this principle. In some embodiments, the transmitting module 810, the receiving module 820, the processing module 830, the first monitoring module 840, the second monitoring module 850, and the third monitoring module 860 as disclosed in FIG. 8 may be different modules in a single system or may be a single module that implements the functions of two or more of the above-described modules. For example, each module may share a common storage module, and each module may have a respective storage module. Morphs such as these are within the scope of protection of the present disclosure.

FIG. 9 is a flowchart illustrating an exemplary magnetic resonance imaging method according to some embodiments of the present disclosure. As shown in FIG. 9, process 900 includes the following operations. In some embodiments, process 900 may be performed by the MRI device 140.

In 910, a nuclear spin magnetic field signal of an object collected by a magnetic sensor array in the MRI system is acquired. In some embodiments, operation 910 may be performed by the receiving module 820.

In conjunction with the foregoing, when a hydrogen atom nucleus within the object releases energy, a change in a near-magnetization vector of the hydrogen atom is received by a signal receiving assembly (e.g., the signal receiving assembly 211), and the sum of the amount of the change in the near-magnetization vector of all hydrogen atoms of the object that is received is the nuclear spin magnetic field signal of the object. The nuclear spin magnetic field signal may be characterized based on the electrical signal and time curve output from the bridge circuit in the magnetic sensor array.

Before applying the RF pulse to the object, the hydrogen nucleus in the object is in the superposition field of the static magnetic field and the gradient magnetic field, and the direction of the near-magnetization vector of the hydrogen nucleus is the same as the direction of the magnetic field of the superposition field at the location of the hydrogen nucleus. The magnitude of the near-magnetization vector is positively correlated to the magnitude of the magnetic field of the superposition field at the location of the hydrogen nucleus. When the RF pulse is applied to the object, the hydrogen nucleus in the object resonates under the action of the RF pulse, and the magnitude and direction of the near-magnetization vector of the hydrogen nucleus in the object change under the influence of the RF pulse, and each TMR sensor in a TMR sensor array may monitor the sum of the amount of the change in the near-magnetization vector of the hydrogen nucleus in an imaging part of the object at resonance, thus leading to a change in the resistance of the TMR sensor array and causing a change in the electrical signal output by the bridge circuit. The changed electrical signal is the nuclear spin magnetic field signal.

In some embodiments, if a plurality of the first magnetic sensors in the magnetic sensor array are connected to the same bridge circuit, the electrical signal output from the bridge circuit may be determined to be the nuclear spin magnetic field signal in the time domain. If a plurality of first magnetic sensors in the magnetic sensor array are separately connected to a plurality of bridge circuits, the nuclear spin magnetic field signal may be determined based on the electrical signals output from the plurality of bridge circuits. For example, an average value of the electrical signals output from the plurality of bridge circuits may be determined as the nuclear spin magnetic field signal in the time domain.

In some embodiments, the static magnetic field and/or the gradient magnetic field of the MRI device is turned off during the acquisition of the nuclear spin magnetic field signal of the object.

In some embodiments of the present disclosure, by turning off the static magnetic field and/or gradient magnetic field of the MRI device during the process of acquiring the nuclear spin magnetic field signal of the subject, the effects of the static magnetic field and the gradient magnetic field on the nuclear spin magnetic field signal may be avoided, thereby reducing the amount of noise in the final imaging result.

In 915, metal detection is performed using a third monitoring assembly of the MRI system. In some embodiments, before sending the object into the scanning aperture or emitting RF pulses, the third monitoring assembly of the MRI system may be used for the metal detection. More descriptions regarding the third monitoring assembly may be found in FIG. 2, FIG. 7, and their related descriptions.

The third monitoring assembly includes one or more magnetic sensors, for example, the third monitoring assembly includes one or more fourth magnetic sensors.

In conjunction with the foregoing, the metal detection includes monitoring whether the redundant metal presents in a monitoring region, the monitoring region at least including a scanning bed. The third monitoring module (e.g., the third monitoring module 860) may determine whether the redundant metal presents in the monitoring region by monitoring the change in current value via a current monitoring device in the connected external circuit. For example, if the current value monitored by the current monitoring device changes by an amount greater than a preset current change threshold within a preset time period (e.g., 0.1 s), it may be determined that redundant metal exists in the monitoring region.

More descriptions regarding the third monitoring assembly, the fourth magnetic sensor, and metal detection may be found in FIG. 2, FIG. 7, and their related descriptions.

Some embodiments of the present disclosure expand the use of magnetic sensors in the MRI system by using the second monitoring assembly to monitor the operation information and the third monitoring assembly to perform the metal detection and achieve the effect of utilizing the magnetic sensor as a detector to monitor device malfunctions and potential safety issues.

In 920, K-space data is determined based on the nuclear spin magnetic field signal. In some embodiments, step 920 may be performed by processing module 830.

The K-space data refers to the data obtained after filling the nuclear spin magnetic field signal into K-space (a frequency domain space).

The method of filling may be a Fourier transform. Based on this, the processing module 830 or data processor (e.g., the processing device 110) may convert the nuclear spin magnetic field signal into K-space data based on the Fourier transform. More descriptions regarding the K-space data may be found in FIG. 6 and its related descriptions.

In 930, the magnetic resonance image of the object is obtained by image reconstruction based on K-space data. In some embodiments, step 930 may be performed by processing module 830.

The magnetic resonance image refers to an image of an imaging part of the object obtained by the MRI system (e.g., the MRI device 140).

The image reconstruction may be implemented by inverse Fourier transform algorithms, interpolation algorithms, phase-corrected conjugate synthesis algorithms, convex set projection algorithms, etc. Based on this, exemplarily, the processing module 830 or the data processor (e.g., the processing device 110) may transform the K-space data to obtain the magnetic resonance image based on an inverse Fourier transform.

In some embodiments, as shown in FIG. 9, the process 900 further includes operation 940, operation 950, and/or operation 960.

In 940, the magnetic field distribution information of the static magnetic field and/or the gradient field is monitored using the first monitoring assembly of the MRI system. In some embodiments, operation 940 may be performed in real time during the MRI of the object (e.g., before, during, and after the RF pulse is emitted, before, during, and after the nuclear spin magnetic field signal is acquired, etc.). It should be noted that when the static magnetic field and/or gradient magnetic field of the MRI device are turned off during the process of acquiring the nuclear spin magnetic field signal of the object, the static magnetic field and/or gradient magnetic field may not be monitored. More descriptions regarding the first monitoring assembly and the magnetic field distribution information may be found in FIG. 2, FIG. 6, and related descriptions thereof.

In some embodiments, to avoid signal interference, when monitoring the magnetic field distribution information of the static magnetic field and/or gradient magnetic field using the first monitoring assembly of the MRI system, the primary magnetic field may be turned off or shielded (e.g. by setting a shielding assembly). In some embodiments, compensation calculation may be performed on the monitored signals of the static magnetic field and/or the gradient magnetic field based on a preset signal compensation parameter (such as a signal compensation parameter preset by the user based on experience or historical data) or a real-time calculated signal compensation parameter (such as a signal compensation parameter predicted in real-time based on real-time field strength information of the MRI system using a machine learning model), to compensate for the interference generated by the primary magnetic field or other magnetic field signals

In some embodiments of the present disclosure, by monitoring the magnetic field distribution information of the static magnetic field and/or the gradient magnetic field in real time, timely adjustments may be made to the static magnetic field and/or the gradient magnetic field when the static magnetic field and/or the gradient magnetic field show large fluctuations, so as to avoid adverse effects of the fluctuations on imaging results.

In 950, the operation information is monitored using a second monitoring assembly of the MRI system. In some embodiments, operation 950 may be performed in real time during the MRI of the object (e.g., before, during, and after the RF pulse is emitted, before, during, and after the nuclear spin magnetic field signal is acquired, etc.).

The second monitoring assembly includes one or more magnetic sensors. For example, the second monitoring assembly includes one or more third magnetic sensors.

In conjunction with the foregoing, the operation information may include magnetic field anomaly information and/or failure information. The second monitoring module (e.g., the second monitoring module 850) may determine the magnetic field anomaly information or failure information by monitoring the magnetic induction strength of the static magnetic field and/or the gradient magnetic field.

More descriptions regarding the second monitoring assembly, the third magnetic sensor, and the operation information may be found in FIG. 2, FIG. 7, and their related descriptions.

It should be noted that the foregoing description of the process 900 is intended to be exemplary and illustrative only and does not limit the scope of application of the present disclosure. For a person skilled in the art, various corrections and changes may be made to the process 900 under the guidance of the present disclosure. However, these corrections and changes remain within the scope of the present disclosure. For example, operations 940 and 950 are combined into a single operation.

Having thus described the basic concepts, it may be rather apparent to those skilled in the art after reading this detailed disclosure that the foregoing detailed disclosure is intended to be presented by way of example only and is not limiting. Although not explicitly stated here, those skilled in the art may make various modifications, improvements, and amendments to the present disclosure. These alterations, improvements, and amendments are intended to be suggested by this disclosure and are within the spirit and scope of the exemplary embodiments of the present disclosure.

Moreover, certain terminology has been used to describe embodiments of the present disclosure. For example, the terms “one embodiment,” “an embodiment,” and/or “some embodiments” mean that a particular feature, structure, or feature described in connection with the embodiment is included in at least one embodiment of the present disclosure. Therefore, it is emphasized and should be appreciated that two or more references to “an embodiment”, “one embodiment”, or “an alternative embodiment” in various portions of the present disclosure are not necessarily all referring to the same embodiment. In addition, some features, structures, or characteristics of one or more embodiments in the present disclosure may be properly combined.

Furthermore, the recited order of processing elements or sequences, or the use of numbers, letters, or other designations, therefore, is not intended to limit the claimed processes and methods to any order except as may be specified in the claims. Although the above disclosure discusses some embodiments of the invention currently considered useful by various examples, it should be understood that such details are for illustrative purposes only, and the additional claims are not limited to the disclosed embodiments. Instead, the claims are intended to cover all combinations of corrections and equivalents consistent with the substance and scope of the embodiments of the present disclosure. For example, although the implementation of various components described above may be embodied in a hardware device, it may also be implemented as a software only solution, e.g., an installation on an existing server or mobile device.

Similarly, it should be appreciated that in the foregoing description of embodiments of the present disclosure, various features are sometimes grouped together in a single embodiment, figure, or description thereof for the purpose of streamlining the disclosure aiding in the understanding of one or more of the various embodiments. However, this disclosure does not mean that object of the present disclosure requires more features than the features mentioned in the claims. Rather, claimed subject matter may lie in less than all features of a single foregoing disclosed embodiment.

In some embodiments, the numbers expressing quantities or properties used to describe and claim certain embodiments of the present disclosure are to be understood as being modified in some instances by the term “about”, “approximate”, or “substantially”. For example, “about”, “approximate”, or “substantially” may indicate ±20% variation of the value it describes, unless otherwise stated. Accordingly, in some embodiments, the numerical parameters set forth in the written description and attached claims are approximations that may vary depending upon the desired properties sought to be obtained by a particular embodiment. In some embodiments, the numerical parameters should be construed in light of the number of reported significant digits and by applying ordinary rounding techniques. Notwithstanding that the numerical ranges and parameters setting forth the broad scope of some embodiments of the present disclosure are approximations, the numerical values set forth in the specific examples are reported as precisely as practicable.

Each of the patents, patent applications, publications of patent applications, and other material, such as articles, books, specifications, publications, documents, things, and/or the like, referenced herein is hereby incorporated herein by this reference in its entirety for all purposes. History application documents that are inconsistent or conflictive with the contents of the present disclosure are excluded, as well as documents (currently or subsequently appended to the present specification) limiting the broadest scope of the claims of the present disclosure. By way of example, should there be any inconsistency or conflict between the description, definition, and/or the use of a term associated with any of the incorporated material and that associated with the present document, the description, definition, and/or the use of the term in the present document shall prevail.

In closing, it is to be understood that the embodiments of the present disclosure disclosed herein are illustrative of the principles of the embodiments of the present disclosure. Other modifications that may be employed may be within the scope of the present disclosure. Thus, by way of example, but not of limitation, alternative configurations of the embodiments of the present disclosure may be utilized in accordance with the teachings herein. Accordingly, embodiments of the present disclosure are not limited to that precisely as shown and described.

What is claimed is:

1. A magnetic resonance imaging (MRI) system, comprising:
a signal receiving assembly configured to acquire a magnetic resonance signal of an object; and
a data processor configured to generate a magnetic resonance image of the object based on the magnetic resonance signal, wherein
the signal receiving assembly includes one or more magnetic sensors.

2. The MRI system of claim 1, wherein the one or more magnetic sensors include a plurality of first magnetic sensors arranged non-uniformly.

3. The MRI system of claim 1, wherein a count and/or layout of the one or more magnetic sensors is determined based on a region of interest of the object.

4. The MRI system of claim 1, wherein the one or more magnetic sensors are arranged to form a planar structure or a three-dimensional (3D) structure.

5. The MRI system of claim 1, wherein the one or more magnetic sensors are configured to monitor physiological information of the object.

6. The MRI system of claim 1, further comprising:
a first monitoring assembly including at least one second magnetic sensor configured to monitor magnetic field distribution information of a static magnetic field and/or a gradient field of the MRI system.

7. The MRI system of claim 6, wherein a detection region of the at least one second magnetic sensor is configured to cover an examination region of the MRI system, and the magnetic field distribution information includes at least one of a temporal distribution or a spatial distribution of the static magnetic field and/or the gradient field of the MRI system.

8. The MRI system of claim 6, wherein one of the at least one second magnetic sensor is configured to move in the static magnetic field and/or the gradient field of the MRI system.

9. The MRI system of claim 8, wherein a count of second magnetic sensors that are configured to move in the static magnetic field and/or the gradient field of the MRI system is less than a preset threshold.

10. The MRI system of claim 8, wherein the one of the at least one second magnetic sensor is configured to move in an axial direction or a circumferential direction along an aperture of the MRI system.

11. The MRI system of claim 6, wherein a second magnetic sensor configured to monitor the static magnetic field has a different measurement accuracy and/or a different sampling rate than a second magnetic sensor configured to monitor the gradient field.

12. The MRI system of claim 1, further comprising:
a second monitoring assembly including one or more third magnetic sensors, wherein the second monitoring assembly is configured to monitor operation information of the MRI system.

13. The MRI system of claim 12, wherein the second monitoring assembly is provided at an edge of a scanning bed or an edge of an aperture of the MRI system.

14. The MRI system of claim 12, wherein the one or more third magnetic sensors are different from the one or more magnetic sensors of the signal receiving assembly.

15. The MRI system of claim 1, further comprising:
a third monitoring assembly including one or more fourth magnetic sensors, wherein the third monitoring assembly is configured to perform metal detection.

16. The MRI system of claim 15, wherein the third monitoring assembly is provided within a scanning chamber, at the edge of the scanning bed, or on a frame of the MRI system.

17. A magnetic resonance imaging (MRI) method, comprising:
acquiring a magnetic resonance signal of an object collected by one or more magnetic sensors in an MRI device;
determining K-space data based on the magnetic resonance signal; and
obtaining a magnetic resonance image of the object by image reconstruction based on the K-space data.

18. The method of claim 17, wherein the acquiring a magnetic resonance signal of an object collected by one or more magnetic sensors in an MRI device includes:
turning off at least one of a static magnetic field or a gradient field of the MRI device during a process of acquiring the magnetic resonance signal of the object.

19. The method of claim 17, further comprising:
monitoring magnetic field distribution information of a static magnetic field and/or a gradient field using a first monitoring assembly of the MRI device, the first monitoring assembly including at least one second magnetic sensor.

20. The method of claim 17, further comprising:
monitoring device operation information using a second monitoring assembly of the MRI device, the second monitoring assembly including one or more third magnetic sensors; and/or, performing metal detection using a third monitoring assembly of the MRI device, the third monitoring assembly including one or more fourth magnetic sensors, the metal detection including monitoring whether a redundant metal presents in a monitoring region, the monitoring region at least including a scanning bed.
